(19) United States
(12) Patent Application Publication
(10) Pub. No.: US 2025/0105009 A1
(43) Pub. Date: Mar. 27, 2025

(54) HIGH-PRECISION HETEROGENEOUS INTEGRATION

(71) Applicant: Board of Regents, The University of Texas System, Austin, TX (US)

(72) Inventors: Sidlgata V. Sreenivasan, Austin, TX (US); Paras Ajay, Austin, TX (US)

(21) Appl. No.: 18/728,885

(22) PCT Filed: Jan. 13, 2023
(86) PCT No.: PCT/US2023/010803

§ 371 Date: Jul. 14, 2024

Related U.S. Application Data
(60) Provisional application No. 63/299,631, filed on Jan. 14, 2022.
(60) Provisional application No. 63/357,810, filed on Jul. 1, 2022.

(51) Int. Cl. H01L 21/02; H01L 21/68; H01L 21/683; H01L 21/762; H01L 23/00; H01L 25/00; H01L 25/18

(52) U.S. Cl. CPC H01L 21/02601; H01L 21/681; H01L 21/6835; H01L 21/76251; H01L 24/27; H01L 24/29; H01L 24/32; H01L 25/18; H01L 25/50; H01L 2224/2761; H01L 2224/29019; H01L 2224/32225; H01L 2924/37001

(57) ABSTRACT

A method for implementing high-precision heterogeneous integration. An etch of a first bonding surface and a second bonding surface is performed to create nanostructures in the first bonding surface and/or the second bonding surface. The first and second bonding surfaces are bonded together, where a particle lands at a bonding interface resulting in an exclusion zone that is at least two times smaller than a bonding of two bonding surfaces with no nanostructures.

### CROSS REFERENCE TO RELATED APPLICATIONS

This application claims priority to U.S. Provisional Patent Application Ser. No. 63/299,631 entitled “High Precision Heterogenous Integration,” filed on Jan. 14, 2022, which is incorporated by reference herein in its entirety.

This application further claims priority to U.S. Provisional Patent Application Ser. No. 63/357,810 entitled “High-Precision Heterogeneous Integration,” filed on Jul. 1, 2022, which is incorporated by reference herein in its entirety.

### TECHNICAL FIELD

The present invention relates generally to heterogeneous integration, and more particularly to high-precision heterogeneous integration.

### BACKGROUND

The semiconductor industry is facing a new era in which device scaling and cost reduction will no longer continue on the path followed for the past few decades. Packing more transistors on a monolithic integrated circuit (IC) is becoming more difficult and expensive at each node. Semiconductor companies are now looking for technology solutions to bridge the gap and improve cost-performance, while at the same time adding more functionality through integration. Integrating all the functions into a single chip (known as system on a chip (SoC)) present many challenges that include higher costs and design complexities. An attractive alternative is heterogeneous integration that uses advanced packaging technology to integrate devices which could be separately designed and manufactured by the most suitable process technology in the most optimized way.

Heterogeneous Integration refers to the integration of separately manufactured components into a higher level assembly (System-in-Package (SiP)) that, in the aggregate, provides enhanced functionality and improved operating characteristics.

The combined components can vary in system level (e.g., pre-assembled package or subsystem), functionality (e.g., specialized processors, DRAM, flash memory, surface mount device (SMD), resistor/capacitor/inductor, filters, connectors, MEMS device, sensors) and technologies (e.g., one optimized for die size while another one optimized for low power). The overall idea behind heterogeneous integration is to integrate multiple dies in the same package. This enables the package to perform a specific and advanced function in a small form factor.

By utilizing heterogeneous integration to combine chips with different process nodes and technologies, such technology enables the continued increase in functional density and decrease in cost per function required to maintain the progress in cost and performance for electronics. Heterogeneous integration is essential to maintain the pace of progress with higher performance, lower latency, smaller size, lighter weight, lower power requirement per function and lower cost.

Unfortunately, the precision in integrating separately manufactured components into a higher level assembly (System-in-Package (SiP)) is deficient.

### SUMMARY

In one embodiment of the present disclosure, a method for enhancing a yield of a bonding process comprises performing an etch on one or more of a first bonding surface and a second bonding surface to create nanostructures in the one or more of the first bonding surface and the second bonding surface. The method further comprises bonding the first bonding surface with the second bonding surface, where a particle lands at a bonding interface resulting in an exclusion zone that is at least two times smaller than a bonding of two bonding surfaces with no nanostructures.

In another embodiment of the present disclosure, a method for reducing an impact of particles on a yield of a bonding process comprises performing an etch on one or more of a first bonding surface and a second bonding surface to create island structures. The method further comprises bonding the first bonding surface with the second bonding surface, where a particle lands at a bonding interface resulting in an exclusion zone that is at least two times smaller than a bonding of two bonding surfaces with no nanostructures.

In a further embodiment of the present disclosure, a method for fabricating a semiconductor device comprising two or more known good die comprises bonding the two or more known good die adjacent to each other onto a product substrate with their metal pads facing away from aid product substrate, where a mean thickness of the two or more known good die is substantially the same. The method further comprises performing inter-die gap-fill, planarization and/or metallization to fabricate the semiconductor device after the bonding.

In another embodiment of the present disclosure, a method for creating a substrate populated with two or more known good die comprises bonding the two or more known good die onto the substrate using direct bonding, fusion bonding or hybrid bonding, where a mean thickness of the two or more known good die is substantially the same, and where the substrate comprises etched nanostructures at a bonding interface.

In a further embodiment of the present disclosure, a method for creating a substrate populated with two or more known good die comprises bonding the two or more known good die onto the substrate using adhesive, ultraviolet-curable adhesive, light switchable adhesive or nanoimprint resist, where a mean thickness of the two or more known good die is substantially the same.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 illustrates an exemplary system for pick-and-place assembly in accordance with an embodiment of the present disclosure;

FIG. 2 illustrates an exemplary die stack on a carrier substrate in accordance with an embodiment of the present disclosure;

FIG. 3 illustrates an exemplary die stack on a tape frame in accordance with an embodiment of the present disclosure;

FIG. 4 illustrates an exemplary die stack on a transfer substrate in accordance with an embodiment of the present disclosure;

FIG. 5 illustrates the transfer wafer preparation in accordance with an embodiment of the present disclosure;

FIG. 6 illustrates an exemplary die delamination chuck in accordance with an embodiment of the present disclosure;

FIG. 7 illustrates an exemplary die thickness measurement method in accordance with an embodiment of the present disclosure;

FIG. 8 illustrates an alternative exemplary die thickness measurement method in accordance with an embodiment of the present disclosure;

FIG. 9A illustrates a die encapsulation layer with etched pin structures in accordance with an embodiment of the present disclosure;

FIG. 9B illustrates optional inkjetted and gel-cured polymer-based pins on an encapsulation layer of the die in accordance with an embodiment of the present disclosure;

FIG. 9C illustrates optional compliant pins on the encapsulation layer of the die in accordance with an embodiment of the present disclosure;

FIG. 10A illustrates a top view of the structure of FIG. 9A in accordance with an embodiment of the present disclosure;

FIG. 10B illustrates a top view of the structure of FIG. 9B in accordance with an embodiment of the present disclosure;

FIG. 11 illustrates an exemplary gantry-based Adaptive Multi-chip-transfer System (AMS) in accordance with an embodiment of the present disclosure;

FIG. 12A illustrates a cross-section of the gantry xy stage in accordance with an embodiment of the present disclosure;

FIG. 12B illustrates an alternative cross-section of the gantry xy stage in accordance with an embodiment of the present disclosure;

FIG. 13A illustrates the die prior to dicing in accordance with an embodiment of the present disclosure;

FIG. 13B illustrates the die post-dicing in accordance with an embodiment of the present disclosure;

FIG. 14A illustrates the x/y distance between the bottom-side main alignment marks shown in FIGS. 13A and 13B in accordance with an embodiment of the present disclosure;

FIG. 14B illustrates that the position of the top and bottom peripheral marks with respect to the circuit elements and main alignment marks is known by design in accordance with an embodiment of the present disclosure;

FIG. 15A illustrates an exemplary massively parallel die actuation method in accordance with an embodiment of the present disclosure;

FIG. 15B illustrates an alternative exemplary massively parallel die actuation method in accordance with an embodiment of the present disclosure;

FIGS. 16A-16C illustrate the direct die-to-wafer (D2W) bonding approach in accordance with an embodiment of the present disclosure;

FIG. 17A illustrates an apparatus for die thinning in accordance with an embodiment of the present disclosure;

FIG. 17B illustrates a die thinning approach using the apparatus of FIG. 17A in accordance with an embodiment of the present disclosure;

FIG. 17C illustrates an alternative die thinning approach using the apparatus of FIG. 17A in accordance with an embodiment of the present disclosure;

FIG. 18A illustrates an apparatus for particle removal in accordance with an embodiment of the present disclosure;

FIG. 18B illustrates an exemplary particle removal approach using the apparatus of FIG. 18A in accordance with an embodiment of the present disclosure;

FIG. 19 is a flowchart of a method for performing direct bonding in accordance with an embodiment of the present disclosure;

FIGS. 20A-20F depict the cross-sectional views for performing direct bonding using the steps described in FIG. 19 in accordance with an embodiment of the present disclosure;

FIG. 21 is a flowchart of an alternative method for performing direct bonding in accordance with an embodiment of the present disclosure;

FIGS. 22A-22F depict the cross-sectional views for performing direct bonding using the steps described in FIG. 21 in accordance with an embodiment of the present disclosure;

FIG. 23 is a flowchart of a further method for performing direct bonding in accordance with an embodiment of the present disclosure;

FIGS. 24A-24G depict the cross-sectional views for performing direct bonding using the steps described in FIG. 23 in accordance with an embodiment of the present disclosure;

FIG. 25 illustrates a die cooling solution in accordance with an embodiment of the present disclosure;

FIG. 26 is a cross-section of the die and the heat spreader layer of FIG. 25 in accordance with an embodiment of the present disclosure;

FIG. 27 illustrates an alternative die cooling solution in accordance with an embodiment of the present disclosure;

FIG. 28 is a flowchart of a method for integrating thinned dies with a heat spreader in accordance with an embodiment of the present disclosure;

FIGS. 29A-29C depict the cross-sectional views for integrating thinned dies with a heat spreader using the steps described in FIG. 28 in accordance with an embodiment of the present disclosure;

FIG. 30 illustrates an exemplary assembly of SiPs using hierarchical feedstock chips in accordance with an embodiment of the present disclosure;

FIG. 31 is a flowchart of a method for fabricating SiPs in accordance with an embodiment of the present disclosure;

FIGS. 32A-32F depict the cross-sectional views for fabricating SiPs using the steps described in FIG. 31 in accordance with an embodiment of the present disclosure;

FIG. 33 is an alternative method for fabricating SiPs in accordance with an embodiment of the present disclosure;

FIGS. 34A-34D depict the cross-sectional views for fabricating SiPs using the steps described in FIG. 33 in accordance with an embodiment of the present disclosure;

FIG. 35 is a flowchart of a method for performing heterogeneous integration in accordance with an embodiment of the present disclosure;

FIGS. 36A-36D depict the cross-sectional views for performing heterogeneous integration using the steps described in FIG. 35 in accordance with an embodiment of the present disclosure;

FIG. 37 illustrates the details regarding the heterogeneous integration process in accordance with an embodiment of the present disclosure;

FIGS. 38A-38B illustrate a wafer-to-wafer bonding method in accordance with an embodiment of the present disclosure;

FIGS. 39A-39B illustrate an alternative wafer-to-wafer bonding method in accordance with an embodiment of the present disclosure;

FIGS. 40A-40C illustrate a nano/micropatterned support wafer in accordance with an embodiment of the present disclosure;

FIG. 41 is a flowchart of a method for creating a reconstituted wafer for face to back (F2B) bonding in accordance with an embodiment of the present disclosure;

FIGS. 42A-42N depict the cross-sectional views for creating a reconstituted wafer for face to back (F2B) bonding using the steps described in FIG. 41 in accordance with an embodiment of the present disclosure;

FIG. 43 is a flowchart of an alternative method for creating a reconstituted wafer for face to back (F2B) bonding in accordance with an embodiment of the present disclosure; and

FIGS. 44A-44F depict the cross-sectional views for creating a reconstituted wafer for face to back (F2B) bonding using the steps described in FIG. 43 in accordance with an embodiment of the present disclosure.

### DETAILED DESCRIPTION

As stated in the Background section, the semiconductor industry is facing a new era in which device scaling and cost reduction will no longer continue on the path followed for the past few decades. Packing more transistors on a monolithic integrated circuit (IC) is becoming more difficult and expensive at each node. Semiconductor companies are now looking for technology solutions to bridge the gap and improve cost-performance, while at the same time adding more functionality through integration. Integrating all the functions into a single chip (known as system on a chip (SoC)) present many challenges that include higher costs and design complexities. An attractive alternative is heterogeneous integration that uses advanced packaging technology to integrate devices which could be separately designed and manufactured by the most suitable process technology in the most optimized way.

Heterogeneous Integration refers to the integration of separately manufactured components into a higher level assembly (System-in-Package (SiP)) that, in the aggregate, provides enhanced functionality and improved operating characteristics.

The combined components can vary in system level (e.g., pre-assembled package or subsystem), functionality (e.g., specialized processors, DRAM, flash memory, surface mount device (SMD), resistor/capacitor/inductor, filters, connectors, MEMS device, sensors) and technologies (e.g., one optimized for die size while another one optimized for low power). The overall idea behind heterogeneous integration is to integrate multiple dies in the same package. This enables the package to perform a specific and advanced function in a small form factor.

By utilizing heterogeneous integration to combine chips with different process nodes and technologies, such technology enables the continued increase in functional density and decrease in cost per function required to maintain the progress in cost and performance for electronics. Heterogeneous integration is essential to maintain the pace of progress with higher performance, lower latency, smaller size, lighter weight, lower power requirement per function and lower cost.

Unfortunately, the precision in integrating separately manufactured components into a higher level assembly (System-in-Package (SiP)) is deficient.

The principles of the present invention provide a means for improving the precision in integrating separately manufactured components into a higher level assembly (System-in-Package (SiP)) as discussed further below.

Prior to discussing the Figures, the following provides definitions for various terms used herein.

SiP, as used herein, refers to system-in-package. A SiP is formed of separately manufactured dice that have been physically and/or functionally integrated so as to create a system larger than the individual dice. It is used interchangeably with the term Multi-Chip Module (MCM), 2.5D IC and 3D IC.

Field, as used herein, refers to individual die or a small cluster of die collocated in the SiP.

SPP, as used herein, refers to SiP Pitch on Product-substrate (SPP) including SPPx and SPPy.

Adaptive Multi-chip-transfer System (AMS), as used herein, refers to a system that is used to transfer fields and/or dies from one substrate to another while maintaining thermo-mechanical stability of said fields and/or dies.

Variable Pitch Mechanism (VPM), as used herein, is used to change the pitch of the dies prior to placement onto a transfer/product/intermediate substrate.

Chucking Module (CM), as used herein, is used to securely hold dies of non-arbitrary and/or arbitrary lateral dimension (within pre-defined maximum and minimum lateral dimensions), in a thermo-mechanically stable manner. CM and its auxiliary systems (such as the CM receptacle) as well as one or more dies that are being held by the CM are referred to, interchangeably, as the CM system and the CM assembly.

The term alignment, as used herein, is used interchangeably with overlay and placement.

Metrology microscope assembly, as used herein, refers to a sub-system for measuring the alignment of dies with respect to a reference. This could consist of the metrology optics, imagers and electronics.

Actuation units, as used herein, are used to actuate one or more dies along one or more of the X, Y, Z, Ox, Oy and Oz axes. These could also be used to create deformation in the one or more dies. The actuation units are also referred to herein as short-stroke actuators and short-stroke stages.

The term wafer, as used herein, is used interchangeably with the word substrate.

Light-switchable adhesive (LSA), as used herein, is a class of adhesive materials that can switch their phase and/or their adhesive strength upon exposure to specific wavelengths of light in a reversible manner.

The terms dice and dies are used interchangeably herein.

The abbreviation “PL” stands for photolithography.

The abbreviation “NIL” stands for nanoimprint lithography. NIL also incorporates Jet and Flash Imprint Lithography (J-FIL).

Adhesive, as used herein, is a material that can be used to join two surfaces together (temporarily or permanently). Adhesive can be comprised of one or more of the following materials: die gap fill materials, curable dielectric materials (for instance, UV curable dielectric materials), silicon low-k dielectrics (SiLK), hydrogen silsesquioxane (HSQ), spin-on-glass materials, spin-on-dielectrics, flowable oxides and light-switchable adhesive (LSA).

Bonding, as used herein, is a process for temporary or permanent attachment of one die/substrate with another die/substrate. The bonding may be bump bonding, micro-bump bonding, eutectic bonding, thermocompression bonding, hybrid bonding, anodic bonding, fusion bonding, solder bump bonding, wire bonding, etc. In one embodiment, during bonding, in-situ metrology is performed using one or more of the following methods: moiré metrology or optionally using an imaging-based system (monitoring the absolute position of the dies, optionally with an interferometric stage, and a sensor monitoring any global motion of the two bonding bodies with respect to each other). Also, during bonding, the die being bonded could be curved in a concave or convex manner fashion (for ease of optional adhesive curing and escape of volatiles).

In one embodiment, a generic direct bonding process (hybrid/fusion bonding) utilizes water during the bonding process. In one embodiment, the water is dispensed onto the bonding surfaces using spin coating, inkjetting, slot-die coating, etc. In one embodiment, just enough water is dispensed to create a thin layer (50 nm, 100 nm, 200 nm, etc.). Excess water could go into micro/nanoscale recesses near the bonding surfaces. In one embodiment, in-liquid align, in a manner similar to NIL, is performed as the two bonding surfaces are urged together. In one embodiment, the in-liquid align happens in 100s of millisecond time frames. If adhesives are used in the bonding interface, the adhesives would only be dispensed in the regions that do not contain metal (optionally in recessed regions). In one embodiment, the rheology of the adhesive is optimized to increase or decrease the amount of time available for in-liquid align (for instance, see U.S. Pat. Nos. 6,916,584, 6,919,152 and 6,921,615 which are incorporated by reference herein in their entirety). With UV-curable adhesives, light waveguiding may be used at the interface between the two surfaces being bonded (optionally through recesses) to cure the adhesive.

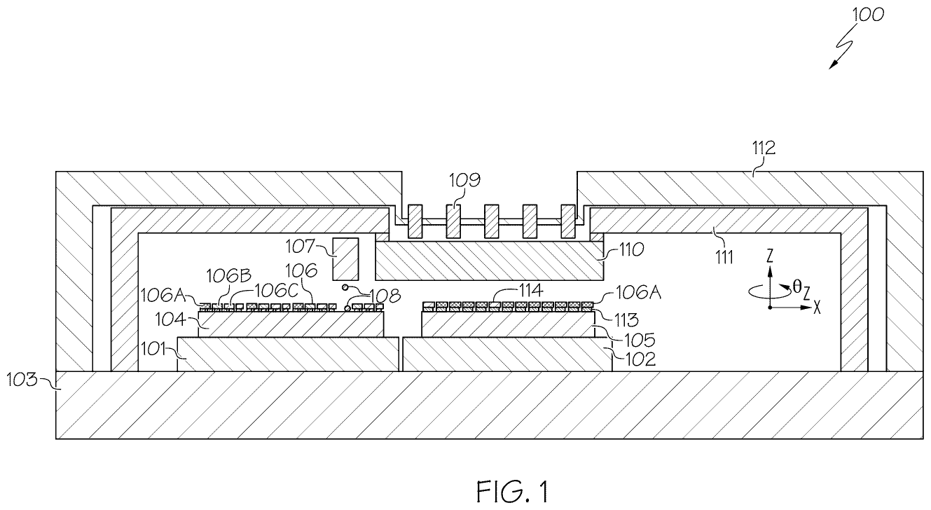

Referring now to FIG. 1, FIG. 1 illustrates an exemplary system 100 for pick-and-place assembly in accordance with an embodiment of the present disclosure.

As shown in FIG. 1, such a system 100 includes a transfer substrate chuck 101 and a source substrate chuck 102 residing on XY motion stage 103. As further shown in FIG. 1, transfer substrate chuck 101 holds transfer substrate 104 and source substrate chuck 102 holds source substrate 105. Furthermore, as shown in FIG. 1, various die 106, such as die 106A (“Die A”), die 106B (“Die B”) and die 106C (“Die C”), are picked from a source substrate, such as source substrate 105, and placed onto transfer substrate 104. Dies 106A-106C may collectively or individually be referred to as dies 106 or die 106, respectively. It is noted that any number of dies 106 may be picked up from source substrate 105 and placed onto transfer substrate 104 and that the number illustrated in FIG. 1 is used for exemplary purposes.

As further shown in FIG. 1, system includes 101 an optional inkjet 107 for dispensing adhesive 108.

Additionally, as shown in FIG. 1, system 100 includes optional alignment microscopes 109 and an Adaptive Multi-chip-transfer System (AMS) 110 for picking up one or more dies 106 from source substrate 105 and placing them onto transfer substrate 104.

Furthermore, as shown in FIG. 1, AMS frame 111 and stable metrology frame 112 are mounted on xy motion stage 103.

Additionally, as shown in FIG. 1, die release adhesive 113 is used to release a die 106, from source substrate 105, such as die 106A.

FIG. 1 further illustrates a bad die 114 in which the die did not meet the electrical requirements of the test program.

A further explanation of FIG. 1 is provided below.

In one embodiment, the transfer chuck (AMS) 110 is used for picking up one or more dies 106 from source substrate 105 and placing them onto a product substrate. In one embodiment, AMS 110 is used to permanently bond the picked dies 106 onto the product substrate. The bonding could be one or more of the following kinds-bump bonding, micro-bump bonding, eutectic bonding, thermocompression bonding, hybrid bonding, anodic bonding, fusion bonding, solder bump bonding and wire bonding. In one embodiment, system 100 for pick-place assembly contains one or more heaters, high-pressure-creating sub-systems, solder dispense sub-systems, solder reflow sub-systems, plasma cleaning sub-systems or plasma activation subs-systems.

In one embodiment, a high-throughput pick-and-place system (e.g., a chip shooter) is utilized to pick-and-place dies 106 from source substrate 105 to transfer substrate 104. In one embodiment, the throughput of the chip shooter is optimized to match the throughput of other components in series in the pick-and-place assembly line (e.g., adhesive dispense stations, precise alignment modules, etc.).

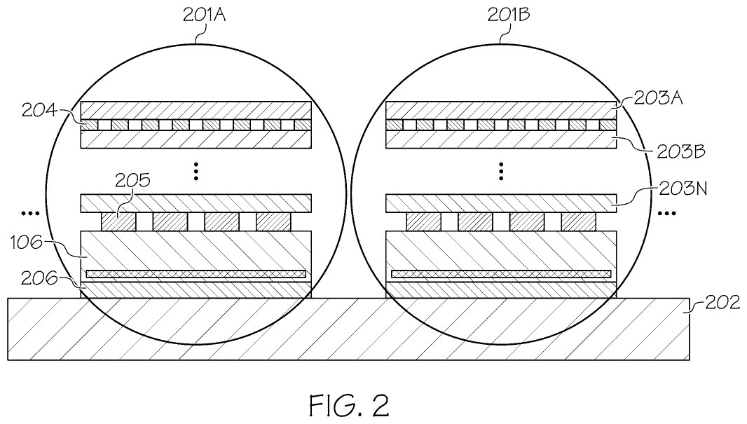

Referring now to FIG. 2, FIG. 2 illustrates an exemplary die stack on a carrier substrate in according with an embodiment of the present disclosure.

As shown in FIG. 2, die stacks 201A-201B are positioned on carrier substrate 202. As further shown in FIG. 2, die stacks 201A-201B include die thickening layer n−1 203A (e.g., silicon oxide), die thickening layer n−2 203B . . . and die thickening layer 1 203N. Die stacks 201A-201B may collectively or individually be referred to as die stacks 201 or die stack 201, respectively. Furthermore, die thickening layers 203A-203N may collectively or individually be referred to as die thickening layers 203 or die thickening layer 203, respectively. While FIG. 2 illustrates two die stacks 201, any number of die stacks 201 may be positioned on carrier substrate 202. Furthermore, each die stack 201 may include any number of die thickening layers 203.

Additionally, as shown in FIG. 2, a gel-cured adhesive 204 is dispensed close to the edges of die thickening layers 203. Furthermore, as shown in FIG. 2, a fully-cured adhesive 205 is dispensed away from the edges of die thickening layer 203, such as die thickening layer 203N.

Furthermore, FIG. 2 illustrates die 106 with the active side facing down and an adhesive 206 (e.g., light-switchable adhesive) between carrier substrate 202 and die 106.

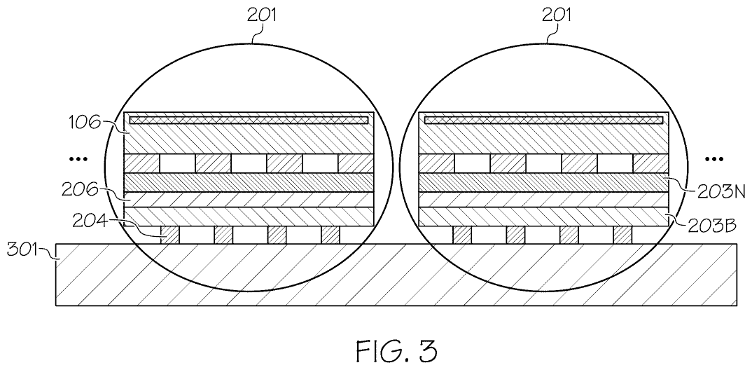

Referring now to FIG. 3, in conjunction with FIG. 2, FIG. 3 illustrates an exemplary die stack on a tape frame in accordance with an embodiment of the present disclosure.

As shown in FIG. 3, die stacks 201 are positioned on tape frame 301 in which gel-cured adhesive 204 is dispensed away from die thickening layer 2 203 B towards the tape film on tape frame 301. Furthermore, as shown in FIG. 3, adhesive 206 (e.g., light-switchable adhesive) is placed between die thickening layers 1 and 2 (203N, 203B).

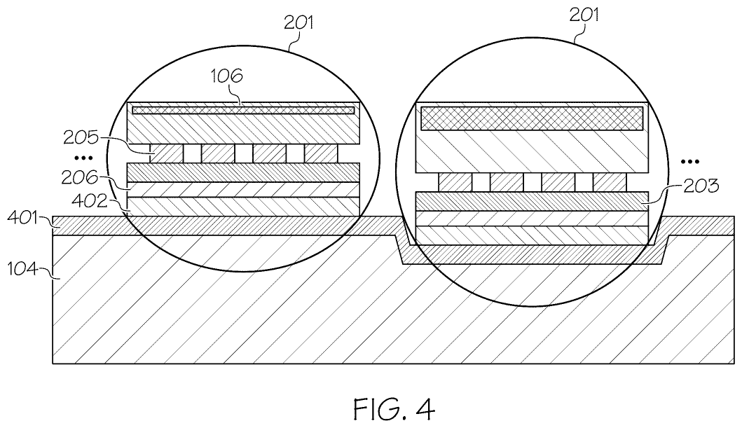

Referring now to FIG. 4, in conjunction with FIGS. 2-3, FIG. 4 illustrates an exemplary die stack on a transfer substrate in accordance with an embodiment of the present disclosure.

As shown in FIG. 4, die stacks 201 are positioned on transfer substrate 104 (e.g., glass, sapphire and/or fused silica) using an optional spin-coated adhesive layer 401 between transfer substrate 104 and a die thickening layer 203 of die stack 201 that is transparent (labeled as element 402).

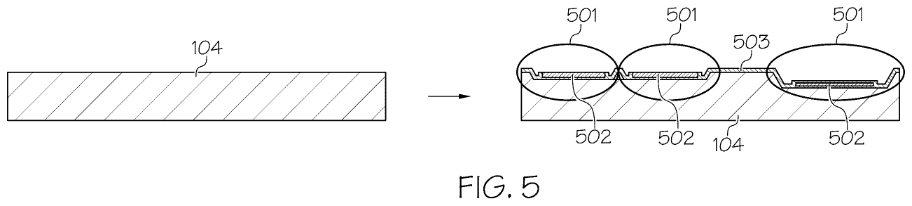

Referring now to FIG. 5, FIG. 5 illustrates the transfer wafer preparation in accordance with an embodiment of the present disclosure.

As shown in FIG. 5, height adjustment zones (or recesses) 501 are created in transfer wafer 104. In one embodiment, such zones 501 are created using a patterning technique, such as photolithography, nanoimprint lithography, direct laser lithography or electron beam lithography, followed by wet etching.

In one embodiment, an adhesive coating 502 may optionally be inkjetted to correct for die thickness variation due to total thickness variations (TTV).

Furthermore, as shown in FIG. 5, in one embodiment, “chip-shooter” glue 503 may be spin-coated on the surface of transfer substrate 104 to implement chip-shooter (placement technology for low precision, simple package components, such as resistors and capacitors, in electronic packaging).

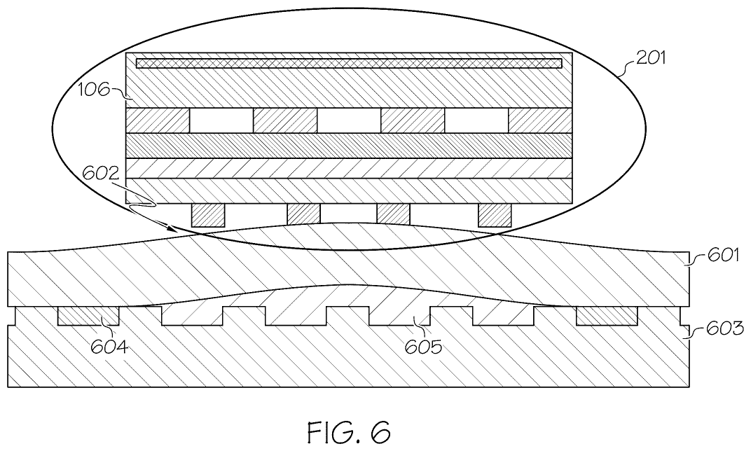

Referring now to FIG. 6, FIG. 6 illustrates an exemplar die delamination chuck in accordance with an embodiment of the present disclosure.

As shown in FIG. 6, die stack 201 is placed on a locally deformed carrier substrate 601 (carrier substrate 202 that is locally deformed) in which delamination (marking the limits or boundary) is initiated at interface 602. Furthermore, as shown in FIG. 6, locally deformed carrier substrate 601 is placed on a portion of a substrate chuck (carrier substrate chuck) 603 in the manner as shown in FIG. 6 using addressable local vacuum 604 and addressable local pressure 605.

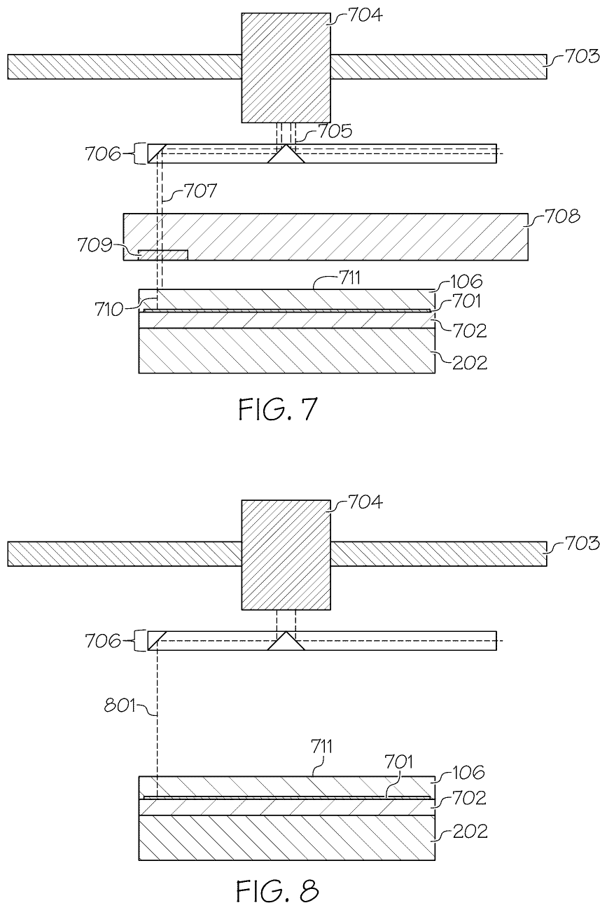

Referring now to FIG. 7, FIG. 7 illustrates an exemplary die thickness measurement method in accordance with an embodiment of the present disclosure.

As shown in FIG. 7, die 106 is facing down so that the bottom portion of the circuit elements 701 is attached to carrier substrate 202, such as during back-grinding, via adhesive 702 (e.g., light-switchable adhesive 206).

Furthermore, as shown in FIG. 7, there is an optional variable pitch mechanism (VPM) 703 along with an exemplary optics and imaging assembly 704, which emits a dual-beam 705 to sense the thickness of die 106 from the die backside 711 (backside of die 106) to the bottom portion of the circuit elements 701 (thickness of the circuit elements is known precisely).

Additionally, as shown in FIG. 7, an optional mirror assembly 706 is utilized to sense multiple marks using a single imager assembly. Furthermore, FIG. 7 illustrates an exemplary visible light path 707, where the visible beam reflects from the bottom of die 106 (die 106 is facing down).

Furthermore, FIG. 7 illustrates a thickness sensing substrate 708 with chirped moiré marks 709 at SiP (system in package) pitch. Additionally, FIG. 7 illustrates an exemplary infrared (IR) light path 710, where the IR beam reflects from the bottom portion of the circuit elements 701 (which act as a reflective medium for the IR light).

Referring now to FIG. 8, FIG. 8 illustrates an alternative exemplary die thickness measurement method in accordance with an embodiment of the present disclosure.

As shown in FIG. 8, in comparison to the exemplary die thickness measurement method of FIG. 7, an IR beam 801 reflects from the bottom portion of the circuit elements 701 (which act as a reflective medium for the IR light) and from the die backside 711. The interference of the two reflected beams may be used to infer die thickness information.

Referring now to FIG. 9A, FIG. 9A illustrates a die encapsulation layer with etched pin structures in accordance with an embodiment of the present disclosure.

As shown in FIG. 9A, an encapsulation layer 901 of die 106 is etched to form pin structures 902. A top view of the structure of FIG. 9A is shown in FIG. 10A in accordance with an embodiment of the present disclosure.

Furthermore, FIG. 10A illustrates the vacuum moat 1001 (area of vacuum surrounding die encapsulation layer 901).

Referring now to FIG. 9B, FIG. 9B illustrates an optional inkjetted and gel-cured polymer-based pins 903 on encapsulation layer 901 of die 106 in accordance with an embodiment of the present disclosure. A top view of the structure of FIG. 9B is shown in FIG. 10B in accordance with an embodiment of the present disclosure.

Furthermore, FIG. 10B illustrates the closely spaced inkjetted drops forming a vacuum moat 1002 (area of vacuum surrounding die encapsulation layer 901).

Referring now to FIG. 9C, FIG. 9C illustrates optional compliant pins 904 on encapsulation layer 901 of die 106 in accordance with an embodiment of the present disclosure.

A more detailed description regarding FIGS. 2-8, 9A-9C and 10A-10B is provided below.

In one embodiment, dies 106 on a carrier substrate 202 contain one or more die thickening layers 203 (for instance, dies facing active-side down on the back-grinding carrier substrate 202, or alternatively, dies facing active-side up on transfer substrate 104). In one embodiment, the one or more die thickening layers 203 are transparent. In one embodiment, the one or more die thickening layers 203 are made of silicon oxide, sapphire, silicon nitride, aluminum oxide, fused silica, glass, silicon carbide, polymers and/or metal coatings. In one embodiment, one or more adhesive layers are present between the die thickening layers 203 and between die thickening layer 203 and die 106. In one embodiment, the one or more adhesive layers, such as adhesive layer 206, consist of a light-switchable adhesive, imprint resist and/or epoxy. In one embodiment, the one or more die thickening layers 203, die 106 and carrier substrate 202 are attached to one another using one or more of the following bonding techniques: bump bonding, micro-bump bonding, mass reflow, eutectic bonding, thermocompression bonding, hybrid bonding, anodic bonding and fusion bonding. In one embodiment, the one or more die thickening layers 203 are grown and/or deposited on die 106 using one or more of the following material deposition techniques, such as chemical vapor deposition, physical vapor deposition, electroplating, sputtering, thermal evaporation, etc. In one embodiment, the one or more die thickening layers 203 are transferred onto prior die thickening layers 203, or onto die 106, as a large substrate which is later to be diced using an appropriate dicing technique along with die 106. In one embodiment, the one or more adhesive layers, such as adhesive layer 206, are dispensed using one or more of the following methods: inkjetting, spin-coating, knife-edge coating, etc. In one embodiment, the one or more adhesive layers, such as adhesive layer 204, consist of gel-cured adhesive drops. In one embodiment, gel-cured adhesive drops 204 are composed of a monomeric material. In one embodiment, the adhesive gel solid-to-liquid ratio is modulated by changing the level of oxygen in the curing environment (which could be air or air with added nitrogen). It is noted that higher concentration of oxygen lead to a greater fraction of liquid in the gel and vice-versa. In one embodiment, the curing is performed using UV light.

In one embodiment, dies 106 that are facing active-side-down on the back-grinding carrier substrate 202 are attached to the back-grinding substrate using a light-switchable adhesive.

In one embodiment, an adhesion promoter could be utilized in one or more of the interfaces between the one or more adhesive layers, such as adhesive layer 206, and the one or more of the die thickening layers 203, die 106 and carrier substrate 202. Exemplar adhesion promoters include BARC, ValMat and TranSpin.

The following elements describe generic methods to enable or prevent delamination of multi-layers stacks of adhesives and substrates at specific interfaces. These methods could, for instance, be applied during die pickup from the back-grinding carrier substrate 202 (for direct die-to-wafer assembly), tape film on tape frame 301 (for assembly onto transfer substrate 104), during fine alignment correction of dies 106 on transfer substrate 104, etc.

For example, one such element is the gel-curing time and oxygen concentration. In one embodiment, specific adhesive interfaces are weakened, and specific ones made stronger using the gel curing time and oxygen concentration in the environment. A shorter curing time, and higher oxygen concentration, would both lead to a greater fraction of liquid in the adhesive (oxygen poisoning affects curing quality in commonly used UV cross-linkable materials, such as acrylates).

Another element is the spatial density of adhesive gel drops. Higher density of adhesive gel drops leads to higher adhesion.

A further element is adhesive thickness. Higher thickness of an adhesive in the liquid state (for instance, liquified light-switchable adhesive) leads to a lower adhesive strength. If the thickness exceeds 100 nm or even 1,000 nm, capillary effects, even in the presence of wetting interfaces, are diminished and therefore, the effective adhesion in liquid state is much lower.

Another element is the spatial arrangement of adhesive drops. Adhesive drops dispensed far from the edges lead to easier adhesive delamination initiation compared to adhesive drops dispensed all the way to the edges. For instance, a circular spatial arrangement of adhesive drops, within rectangular dies, lead to delamination initiation near the die vertices where adhesive drops are not present. The greater the distance of the adhesive drops from the edges, the greater the delamination tendency.

A further element is the layer-specific light absorption. In one embodiment, specific adhesive layers are treated to light at a specific wavelength to enable or disable delamination. For instance, a light-switchable adhesive exposed to visible light increases in adhesion. Alternatively, an adhesive with a dispersion of IR-absorbing nanoparticles reduce in its adhesive strength when exposed to IR radiation at a specific wavelength when the polymeric material exceeds its glass transition temperature (T_{g}).

Another element includes the special wafer chucks for delamination initiation as shown in FIG. 6.

In one embodiment, one or more dies 106 that are intended to reside on an SiP are thickened to a pre-defined thickness (prior to integration). Dies 106 from one kind of source substrate could have a unique added thickness. In one embodiment, die thickening is performed using one or more of the following methods: layer transfer (of die thickener) using direct bonding or using an adhesive layer, and/or coating using inkjetting, material deposition (CVD, PVD, sputtering, etc.), spin-coating and/or knife-edge coating.

In one embodiment, die thickening is performed using a layer which is made of one or more magnetic materials (for instance, a non-magnetic material with suspended magnetic particles, films of magnetic materials, such as iron oxide, chromium, barium, and their magnetic compounds). In one embodiment, die thickening is performed using an adhesive to reduce and/or eliminate die thickness variation across a substrate. In one embodiment, the adhesive is dispensed onto the backside of dies 106 to be thickened using inkjetting.

In one embodiment, transfer substrate 104 has etched recesses 501 of varying heights to accommodate dice of various heights, such that the top surface of all dice is at the substantially the same level. Dies 106 could be attached to transfer substrate 104 using one or more of: adhesive, imprint resist, light-switchable adhesive and epoxy. The etched recesses 501 of varying heights could be created using one or more of the following techniques: nanoimprint lithography and nano-molding with a multi-tier template. In one embodiment, transfer substrate chuck 101 contains UV and visible light sources to switch optional light-switchable adhesives embedded in die thickening layers 203 of dies 106. In one embodiment, the UV and/or visible light sources are in an addressable array. In one embodiment, the UV and/or visible light sources are arrays of interspersed UV and visible light LEDs.

In one embodiment, die thickness measurement is performed on dies 106 placed active-side-downwards on carrier substrate 202. In one embodiment, the die thickness measurement is performed prior to back-grinding or post back-grinding. In one embodiment, the die thickness measurement is performed for every die 106 on the substrate or a selected sample of dies 106. In one embodiment, the die thickness measurement is performed at two or more locations on die 106 on which die thickness measurement is performed. In one embodiment, the die thickness measurement is performed using capacitive, optical, electrical and/or mechanical methods. In one embodiment, the die thickness is measured by measuring the distance of the backside of die 106, and the bottom portion of the die circuit elements 701, from special marks on a thickness sensing substrate 708 as shown in FIG. 7. In one embodiment, the die thickness is equal to (d2−d1)+(thickness of circuit elements which is precisely known). In one embodiment, the marks are chirped moiré marks. It is noted that in FIG. 7, the distance measurement from the die backside 711 and the bottom portion of the circuit elements 701, using, for instance, visible and IR light respectively, could either be performed simultaneously or be staggered temporally. In another embodiment, the die thickness measurement is performed using thin film metrology from die backside 711 as shown in FIG. 8. In one embodiment, the IR light of the appropriate wavelength is utilized to create thin film interference between die backside 711 and the bottom portion of the die circuit elements 701. The wavelength of the IR light utilized could be larger than the gap between the die backside 711 and the bottom portion of the die circuit elements 701 (for instance, if the gap is ˜20 μm, a mid-IR light source could be utilized). Alternatively, phase un-wrapping techniques are utilized to ascertain die thickness. In the two embodiments for die thickness measurement just described, instead of using the bottom portion of the circuit elements 701, metal structures in the die kerf region are utilized for thickness measurement prior to dicing. In one embodiment, the metal structures are either structures already present in the die kerf for separate purposes, or structures specifically created for thickness measurement. In one embodiment, the metal structures are repeating structures (for instance, lines and spaces), or a uniform and uninterrupted layer of metal.

In one embodiment, one or more dies 106 contain an encapsulation layer on one or more of their front or backsides, where the encapsulation layer 901 has a vacuum moat 1001, 1002. In one embodiment, encapsulation layer 901 also has pins 902, 903, 904. In one embodiment, pins 902, 903, 904 and/or vacuum moat 1001, 1002 are created using one or more of the following methods: encapsulation layer coating and pattering of pins/moats using patterning techniques (for instance, photolithography and/or nanoimprint lithography). Alternatively, the following methods are utilized to create pins 902, 903, 904 and/or vacuum moats 1001, 1002: ashing of encapsulation layer 901 in select regions using atmospheric pressure plasma jets to create pins 902, 903, 904/moats 1001, 1002, inkjetting of UV-curable fluid in select regions on die 106 and UV-curing dispensed fluid to create pins 902, 903, 904/moats 1001, 1002. Masks for encapsulation layer patterning using nanoimprint lithography are created using one or more of the following techniques: diamond turning, laser ablation and computer numerical control (CNC) machining. In one embodiment, a multi-tiered mask is utilized to perform multi-tiered patterning on dies 106 using nanoimprint lithography. Subsequent etching after resist patterning is utilized to simultaneously create vacuum moats 1001, 1002 in dies 106 as well as dice dies 106 (assuming dies 106 were un-diced prior to the pattering step). In one embodiment, vacuum moat 1001, 1002 and/or pins 902, 903, 904 are created directly in the die substrate (backside or frontside). In one embodiment, pin 902, 903, 904 and/or vacuum moat 1001, 1002 created on dies 106 are compliant in the z-direction. In one embodiment, encapsulation layer 901 used to create vacuum moats 1001, 1002 is removable (for instance, using O₂ plasma ashing). In one embodiment, encapsulation layer 901 consists of one or more of the following materials: carbon, imprint resist, epoxy, polymers, metal layers, chromium, aluminum oxide and light-switchable adhesive. In one embodiment, dedicated equipment is utilized to create said pins 902, 903, 904 and/or vacuum moats 1001, 1002. In one embodiment, a dedicated module, which is integrated into an existing tool, is utilized to create pins 902, 903, 904 and/or vacuum moats 1001, 1002. In one embodiment, the module utilizes a process for fast plasma etching.

In one embodiment, a flat surface with a vacuum hole in its center is utilized to pick and place dies 106 with vacuum moats 1001, 1002.

In one embodiment, the chucking module (CM) has fixed lateral extents that are smaller than the extents of the smallest die 106 in the group of dies 106 being picked and placed using said CM. In one embodiment, the CM is utilized to pick and place thickened dies 106, where die thickening is performed using one or more of the methods described above.

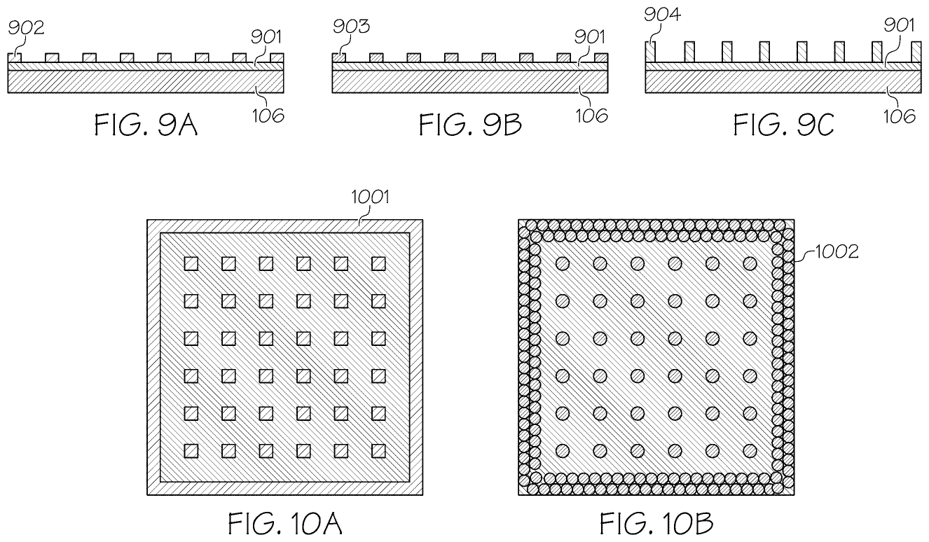

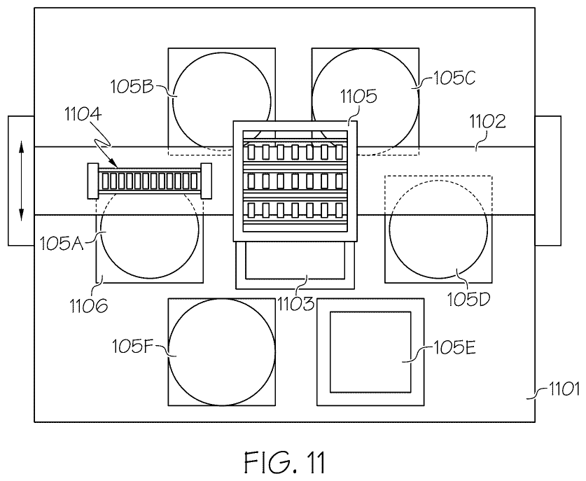

Referring now to FIG. 11, FIG. 11 illustrates an exemplary gantry-based AMS in accordance with an embodiment of the present disclosure.

As shown in FIG. 11, source wafers 105A-105F (e.g., source wafer 1-6) are placed on granite base 1101. Source wafers 105A-105F may collectively or individually be referred to as source wafers 105 or source wafer 105, respectively. Furthermore, FIG. 11 illustrates a gantry xy stage 1102 that is used for marking, labelling, measuring or inspecting source wafers 105, such as source wafer 105A, 105D. Additionally, FIG. 11 illustrates a wafer 1103, such as a transfer wafer 104 or a product wafer.

Additionally, FIG. 11 illustrates an exemplary N×1 AMS 1104 and an exemplary N×M AMS 1105.

Furthermore, as shown in FIG. 11, each source wafer 105 is supported by a long-stroke nano-precise xyθ stage, such as stage 1106.

Referring now to FIG. 12A, FIG. 12A illustrates a cross-section of gantry xy stage 1102 in accordance with an embodiment of the present disclosure.

As shown in FIG. 12A, FIG. 12A illustrates a chucking module (CM) 1201 on gantry-based AMS.

Furthermore, FIG. 12A illustrates circuit elements 1202 of die 106 as well as the die top-side alignment mark 1203.

Additionally, as shown in FIG. 12A, die 106 is positioned on a portion of transfer substrate 104 (acts as the golden reference wafer) via fluid 1204 (e.g., liquified adhesive). Furthermore, as shown in FIG. 12A, the portion of transfer substrate 104 is supported by a portion of transfer substrate chuck 101.

Furthermore, FIG. 12A illustrates an optional variable pitch mechanism (VPM) 703 along with an exemplary optics and imaging assembly 704, which emits a light beam 1205 to sense the thickness of die 106. In one embodiment, light beam 1205 corresponds to infrared (IR) light that is used in the alignment metrology.

Additionally, as shown in FIG. 12A, an optional mirror assembly 706 is utilized to sense multiple marks using a single imager assembly. In connection with such sensing, an optional complimentary mark 1206 on transfer substrate 104 for moiré metrology is utilized.

Referring now to FIG. 12B, FIG. 12B illustrates an alternative cross-section of gantry xy stage 1102 in accordance with an embodiment of the present disclosure.

In comparison to FIG. 12A, gantry xy stage 1102 of FIG. 12B utilizes a die bottom-side alignment mark 1207 as opposed to die top-side alignment mark 1203 shown in FIG. 12A.

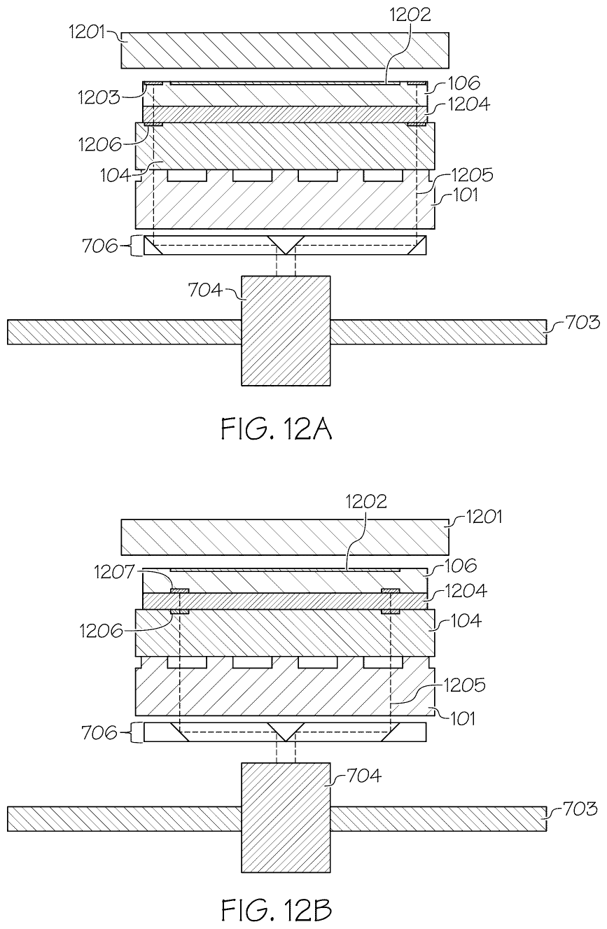

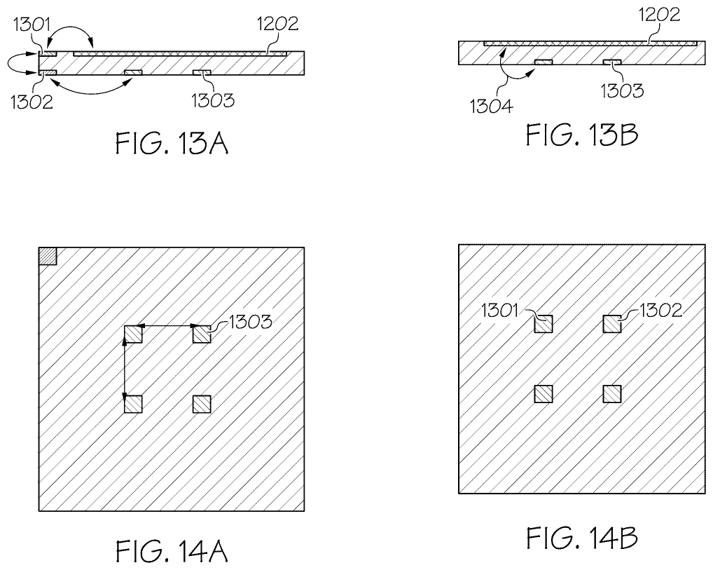

Referring now to FIG. 13A, FIG. 13A illustrates die 106 prior to dicing in accordance with an embodiment of the present disclosure.

As shown in FIG. 13A, die 106 includes top-side peripheral alignment marks 1301, bottom-side peripheral alignment marks 1302 and bottom-side main alignment marks 1303.

Referring now to FIG. 13B, FIG. 13B illustrates the die 106 post-dicing in accordance with an embodiment of the present disclosure.

As shown in FIG. 13B, the relative position 1304 is known.

Referring now to FIG. 14A, FIG. 14A illustrates the x/y distance between the bottom-side main alignment marks 1303 shown in FIGS. 13A and 13B in accordance with an embodiment of the present disclosure.

As shown in FIG. 14A, in one embodiment, the x/y distance between bottom-side main alignment marks 1303 is smaller than the smallest x and y lateral dimensions for all dies 106 on a substrate (e.g., transfer substrate 104, intermediate substrate, product substrate).

Referring now to FIG. 14B, FIG. 14B illustrates that the position of the top and bottom peripheral marks 1301, 1302 with respect to circuit elements 1202 and main alignment marks 1303 is known by design in accordance with an embodiment of the present disclosure. As a result, the alignment between circuit elements 1202 and bottom-side main alignment marks 1303 is obtained by measuring the alignment between peripheral marks 1301, 1302 prior to dicing.

Referring now to FIG. 15A, FIG. 15A illustrates an exemplary massively parallel die actuation method in accordance with an embodiment of the present disclosure.

In particular, FIG. 15A illustrates groups 1501 of dies 106 on an exemplary substrate 1502, where dies 106 are surrounded by light-switchable adhesive 1503.

Furthermore, as shown in FIG. 15A, a carrier 1504 for the grid of actuators utilizes a group of piezoelectric manipulators 1505 to move and control dies 106.

Referring now to FIG. 15B, FIG. 15B illustrates an alternative exemplary massively parallel die actuation method in accordance with an embodiment of the present disclosure.

In comparison to FIG. 15A, FIG. 15B illustrates using electromagnetic actuators 1506 (as opposed to piezoelectric manipulators 1505) to move and control dies 106, which have a surrounding magnetic layer 1507.

Referring now to FIGS. 16A-16C, FIGS. 16A-16C illustrate the direct die-to-wafer (D2W) bonding approach in accordance with an embodiment of the present disclosure.

As shown in FIG. 16A, carrier substrate 202 is held by a substrate chuck 1601. For example, if carrier substrate 202 corresponds to source substrate 105, then source substrate 105 is held by source substrate chuck 102.

In one embodiment, carrier substrate 202 includes diced and backside-thinned dies 106 on a glass carrier. In one embodiment, carrier substrate 202 is chucked on a selective-release chuck 1601.

Furthermore, as shown in FIG. 16A, the active side of dies 106 are facing downwards. Additionally, FIG. 16A illustrates the use of light-switchable adhesive 1503 as previously discussed.

In one embodiment, dies 106 are picked up using AMS 110 as illustrated in FIG. 16B.

In one embodiment, plasma treatment is performed in an optional atmospheric pressure plasma chamber to perform direct bonding as shown in FIG. 16C.

As shown in FIG. 16C, IR metrology 1602 is performed through the backside of die 106. Furthermore, as shown in FIG. 16C, air cushions 1603 are created on the periphery of each die 106 using CM assembly 1201.

Furthermore, as shown in FIG. 16C, dies 106 on carrier substrate 202 are picked and placed on a target substrate, such as product substrate 1604.

In one embodiment, single-wafer die-to-die thickness variation as well as topography variation on product wafer 1604 is compensated for using tip/tilt/z compliance per CM 1201.

In one embodiment, die thickness variation across different source wafers (e.g., source substrate 105) is compensated for using a sequencing approach that assembles the thinnest dies 106 first, etc.

Referring to FIGS. 11, 12A-12B, 13A-13B, 14A-14B, 15A-15B and 16A-16C, in one embodiment, the alignment system for measuring the alignment of dies 106 on a substrate (e.g., transfer substrate 104, source substrate 105, product substrate 1604, intermediate substrate) lies underneath the respective chuck of said substrate. In one embodiment, one or more of the following alignment schemes are utilized for measurement of the die alignment: relative alignment measurement (for instance, using moiré-based alignment schemes) and absolute alignment measurement (for instance, using imaging-based alignment schemes). In one embodiment, the microscopes used in the alignment metrology are low numerical aperture (NA) microscopes. In one embodiment, the microscopes used in the alignment metrology are very low numerical aperture (NA) microscopes. In one embodiment, the microscopes used in the alignment metrology have an NA less than 0.05. In one embodiment, the microscopes used in the alignment metrology have an NA less than 0.01. In one embodiment, the die alignment is measured relative to corresponding marks on a substrate (for instance, transfer substrate 104) that are arranged in a grid with x and y pitches being the SPPx and SPPY. In one embodiment, the marks are moiré alignment marks. In one embodiment, the substrate with the alignment mark grid is also referred to as the golden reference wafer and composed of one or more of thermo-mechanically stable materials (for instance, sapphire, fused silica, glass and silicon). In one embodiment, die pick-and-place is implemented using one or more AMS-es that are mounted onto a gantry stage 1102. In one embodiment, gantry stage 1102 further contains one or more source substrates 105, each of which could be of a unique size and form factor. One or more of the wafers (e.g., source wafers 105, product wafers 1604, transfer wafers 104, intermediate wafers) and corresponding chucks are mounted on an independent XYθ wafer stage.

In one embodiment, the position of the dice on a substrate is changed in parallel, where, a light-switchable adhesive (e.g., adhesive 1503) is present between the dice (e.g., group of dies 106) and the substrate (e.g., substrate 1502), and a group of actuators (e.g., piezoelectric manipulators 1505) are utilized to change the position of one or more of the dice. The group of actuators could be one or more of the following types: piezoelectric (contact-based force application), electrostatic (non-contact force application), and electromagnetic (non-contact force application). In one embodiment, a set of actuators are utilized to change the position of all dies 106 on the substrate (e.g., substrate 1502) in a rigid body manner.

In one embodiment, dies 106 on a carrier substrate 202 (for instance, back-grinding carrier substrate) are picked and placed onto a target substrate (for instance, product substrate 1604) and direct bonded onto the substrate as discussed above in connection with FIGS. 16A-16C. In one embodiment, such bonding is bump bonding, micro-bump bonding, mass reflow, eutectic bonding, thermocompression bonding, hybrid bonding, anodic bonding and/or fusion bonding. In one embodiment, dies 106 are cleaned and surface activated using a plasma prior to hybrid bonding. In one embodiment, the adhesive (e.g., adhesive 1503) between carrier substrate 202 and dies 106 is a light-switchable adhesive. In one embodiment, stray adhesive drops left on dies 106 after pickup are cleaned during the plasma cleaning step. In one embodiment, AMS 110 is used to create fluid cushions (for instance, air cushions) around one or more of the dies 106 being bonded onto product substrate 1604. In case wafer-to-wafer direct bonding is being performed, one of the wafers being bonded could contain through holes (for instance, such through holes are created using deep etching techniques, such as MACE and DRIE), through which air could be sourced to create a fluidic cushion between the two wafers being bonded.

In one embodiment, an array of die testing units is utilized to test a relevant functional characteristic for a group of one or more dies 106 on one or more substrates (e.g., source substrates 105, transfer substrates 104, intermediate substrates, product substrates 1604). Relevant functional characteristic may include electrical performance, power consumption and good/bad die testing. In one embodiment, the array of the die testing units is arranged on a VPM (e.g., VPM 703) which could be used to change the pitch of the die testing units.

In one embodiment, an array of die metrology units is utilized to measure a relevant characteristic for a group of one or more dies 106 on one or more substrates (e.g., source substrates 105, transfer substrates 104, intermediate substrates, product substrates 1604). Relevant characteristics may include die thickness, particle counts, die stress, die bending and quality of one or more deposited layers. In one embodiment, the array of die metrology units is arranged on a VPM (e.g., VPM 703), which could be used to change the pitch of the die metrology units.

Referring now to FIG. 17A, FIG. 17A illustrates an apparatus for die thinning in accordance with an embodiment of the present disclosure.

As shown in FIG. 17A, the apparatus includes a carrier substrate 202 held by a substrate chuck 1601. Furthermore, as shown in FIG. 17A, die adhesive 1503 is placed between carrier substrate 202 and dies 106. In one embodiment, die adhesive 1503 may also optionally act as an encapsulant. Furthermore, in one embodiment, dies 106 have their active side facing downwards.

Additionally, FIG. 17A illustrates diced dies 1701 with die adhesive 1503 coating the sides of the dies.

Furthermore, FIG. 17A illustrates a die thinning module 1702 for thinning dies along with optional short-stroke stages 1703.

FIG. 17B illustrates a die thinning approach using the apparatus of FIG. 17A in accordance with an embodiment of the present disclosure.

As shown in FIG. 17B, FIG. 17B illustrates the die backside 711 being thinned using die thinning module 1702. As further shown in FIG. 17B, a MACE catalyst 1704 is utilized to perform a wet chemical etching of die backside 711 with the use of a metal catalyst. Furthermore, as shown in FIG. 17B, an optional encapsulation layer 1705 is utilized to prevent damage to die thinning module 1702 from MACE catalyst 1704 and the etchant.

FIG. 17C illustrates an alternative die thinning approach using the apparatus of FIG. 17A in accordance with an embodiment of the present disclosure.

Referring to FIG. 17C, die thinning module 1702 includes local temperature controllers 1706 along with locally dispensed MACE etchant 1707, black silicon 1708 and gold (Au) 1709, where die backside 711 is coated with gold 1709.

In one embodiment, die thinning is performed using metal assisted chemical etching (MACE), anodization, silicon anodization, electrochemical etching, electropolishing, inkjet-enabled etching and planarization, and/or plasma etching.

In one embodiment, die thinning is performed using a part (which could be a substrate, or a part of a substrate) that contains one or more machined pillars that are coated with a MACE catalyst (e.g., MAC catalyst 1704). In one embodiment, the part is composed of chromium, steel, gold, metals, silicon, polymers and/or PTFE (polytetrafluoroethylene). In one embodiment, the part is composed of micro-machined silicon coated with an encapsulation layer (for instance, chromium) and a MACE catalyst (for instance, gold).

In one embodiment, die thickness variation is measured using capacitive, optical, electrical and/or mechanical methods. In one embodiment, die thickness variation is measured using the exemplar techniques described in FIGS. 7-8.

In one embodiment, an array of die thinning modules 1702 are used to thin one or more dies 106 simultaneously. In one embodiment, die thinning modules 1702 are placed on a VPM (e.g., VPM 703). In one embodiment, die thickness measurement modules are placed on a VPM (e.g., VPM 703). In one embodiment, control knobs are utilized in die thinning modules 1702 to modulate a local die thinning rate based on feedback from the die thickness measurement modules. In one embodiment, such control knobs control temperature, electric field, radiation of suitable spectrum and/or etchant concentration. In one embodiment, temperature control is implemented using a set of thermoelectric heaters/coolers, incident light of appropriate spectrum, optionally modulated using digital micromirror devices (DMD), fluidic temperature control modules and/or microfluidic temperature control modules. In one embodiment, die thinning modules 1702 are scanned across one or more dies 106. In one embodiment, die thinning modules 1702 are stepped over to one or more dies 106.

In one embodiment, the etchant for die thinning (if required) is dispensed locally around the area being thinned by die thinning module 1702. In one embodiment, the etchant for die thinning (if required) is dispensed in bulk such that one or more die backsides 711 are partially or fully submerged in the etchant.

In one embodiment, die thinning is performed by creating black silicon 1708 on the backside of die 106 (e.g., die backside 711), subsequently oxidizing black silicon 1708, and etching it away using an oxide etch (for instance, using wet or dry HF etching). In one embodiment, black silicon 1708 is produced using electrochemical etching of silicon, silicon anodization, photogeneration-based silicon anodization and/or MACE. In one embodiment, etch depth control is implemented using one or more of the methods described above. In one embodiment, a film of gold is deposited on die backside 711 and used to create black silicon 1708 through the MACE process.

In one embodiment, dies 106 with buried oxide layers (for instance, dies fabricated using SOI wafers), and other buried sacrificial layers (for instance, SiGe), are thinned by removing the bulk substrate from dies 106 using a sacrificial layer etchant (for instance, wet or vapor HF for oxide sacrificial layers). In one embodiment, dies 106 are facing down and attached to a carrier substrate 202 using an adhesive (e.g., adhesive 1503) (that could optionally also act as an encapsulant against the sacrificial layer etchant), while the sacrificial layer etch is being performed.

In one embodiment, diamond thinning and/or polishing is performed using a plasma-based and/or a chemical etching process. In one embodiment, diamond thinning and/or polishing is performed using an oxygen plasma-based process. In one embodiment, diamond thinning and/or polishing is performed using a nickel-based process. Thinning and/or polishing are performed using one or more thinning modules 1702 with thickness feedback obtained from the thickness measurement modules (as previously described).

In one embodiment, dicing is performed prior to die thinning or post die thinning using laser-based, plasma-based, and/or chemical (MACE-based, for instance) methods. In the embodiment in which dicing is performed prior to die thinning, an encapsulation layer is utilized to protect the die frontside during die backside thinning. In one embodiment, the adhesive (e.g., adhesive 1503) that is utilized to attach dies 106 to carrier substrate 202 is also used to protect the die frontside during die backside thinning.

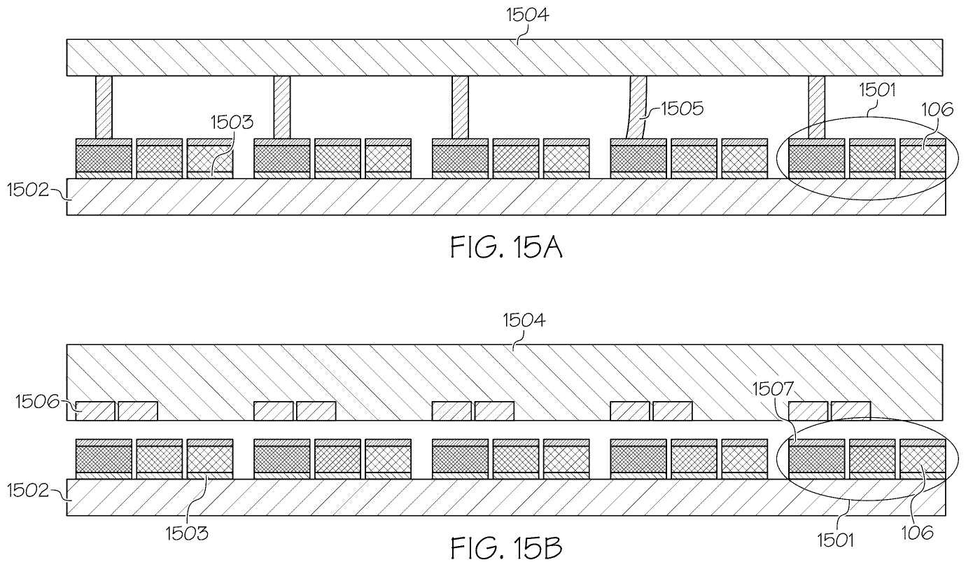

Referring now to FIG. 18A, FIG. 18A illustrates an apparatus for particle removal in accordance with an embodiment of the present disclosure.

As shown in FIG. 18A, the apparatus includes a carrier substrate 202 held by a substrate chuck 1601. Furthermore, as shown in FIG. 18A, die adhesive 1503 is placed between carrier substrate 202 and dies 106. In one embodiment, die adhesive 1503 may also optionally act as an encapsulant. Furthermore, in one embodiment, dies 106 have their active side facing downwards.

Additionally, FIG. 18A illustrates diced dies 1701 with die adhesive 1503 coating the sides of the dies.

Furthermore, FIG. 18A illustrates a particle removing module 1801 for removing particles. Additionally, the apparatus of FIG. 18 optionally includes VPM 703 and short-stroke stages 1703.

FIG. 18B illustrates an exemplary particle removal approach using the apparatus of FIG. 18A in accordance with an embodiment of the present disclosure.

As shown in FIG. 18B, a MACE-based probe 1802 is utilized for removal of particle 1803 on die backside 711. Furthermore, as shown in FIG. 18B, a MACE catalyst 1804 is utilized for removal of particle 1803 on die backside 711. Additionally, as shown in FIG. 18B, locally dispensed MACE etchant 1805 is utilized to etch off particle 1803.

In one embodiment, plasma cleaning, oxygen plasma cleaning, atmospheric pressure plasma cleaning, MACE, pressurized air and/or electrostatic probes are used to remove particles (e.g., particle 1803) from the backside or frontside of dies 106 (e.g., die backside 711). In one embodiment, particles (e.g., particle 1803) on the backside or frontside of dies 106 are sensed using imaging-based, interferometry-based, acoustic, probe-based and/or electrostatic methods. In one embodiment, a set of probes (e.g., probe 1802) is utilized to remove particles (e.g., particle 1803) from the die backside or frontside (e.g., die backside 711). In one embodiment, the set of probes (e.g., probe 1802) utilizes locally dispensed MACE etchants 1805 to etch off particles (e.g., particle 1803), including silicon-based particles. In one embodiment, the set of probes (e.g., probe 1802) utilizes adhesive-based particle pickup (where the probe tip could contain an adhesive that adheres the particle to the probe tip), local sonication and/or local vacuum suction to dislodge the particle (e.g., particle 1803) from die 106 and attach it to the probe (e.g., probe 1802).

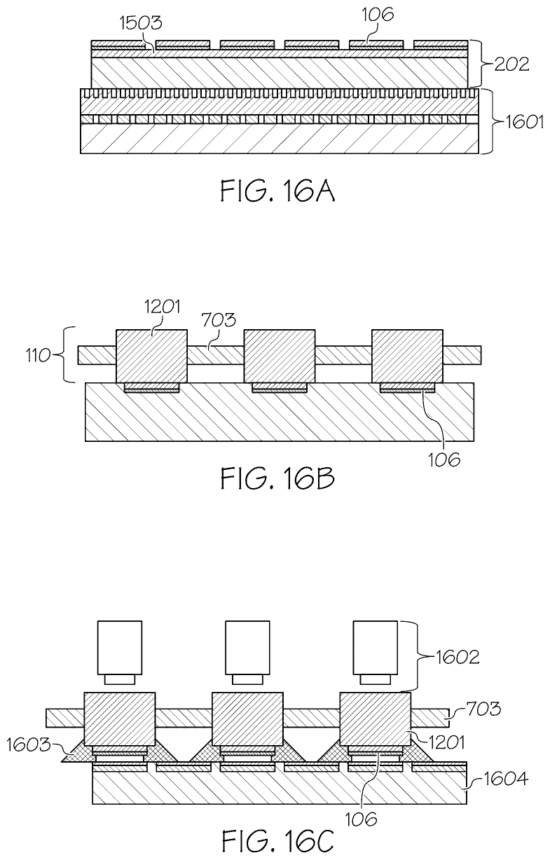

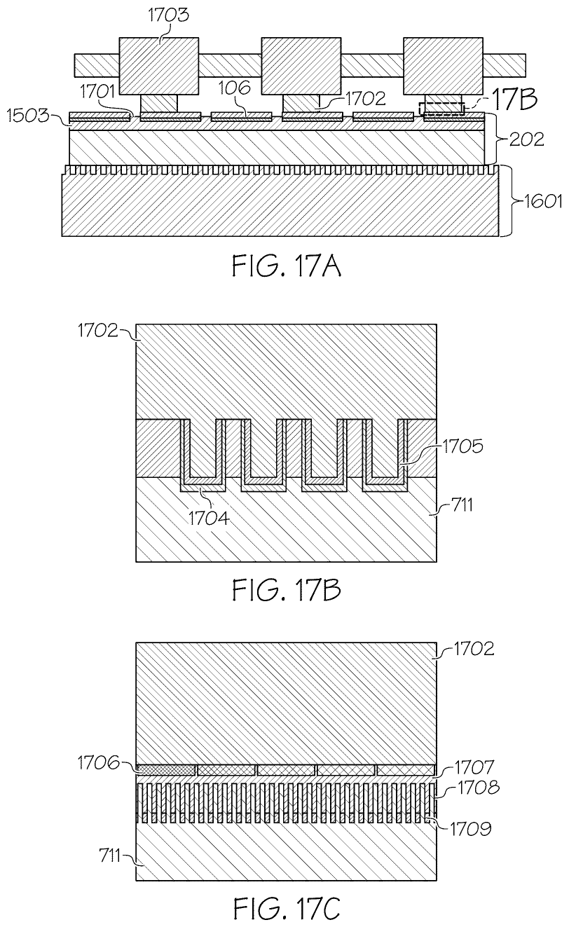

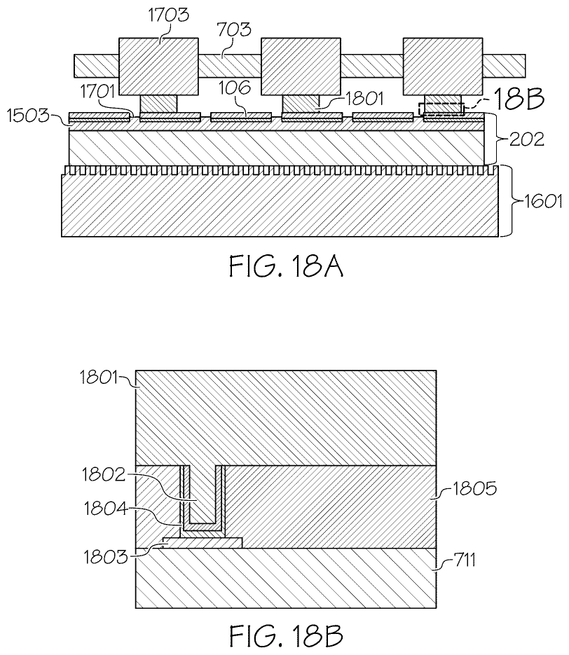

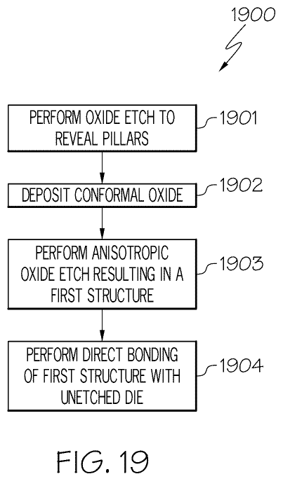

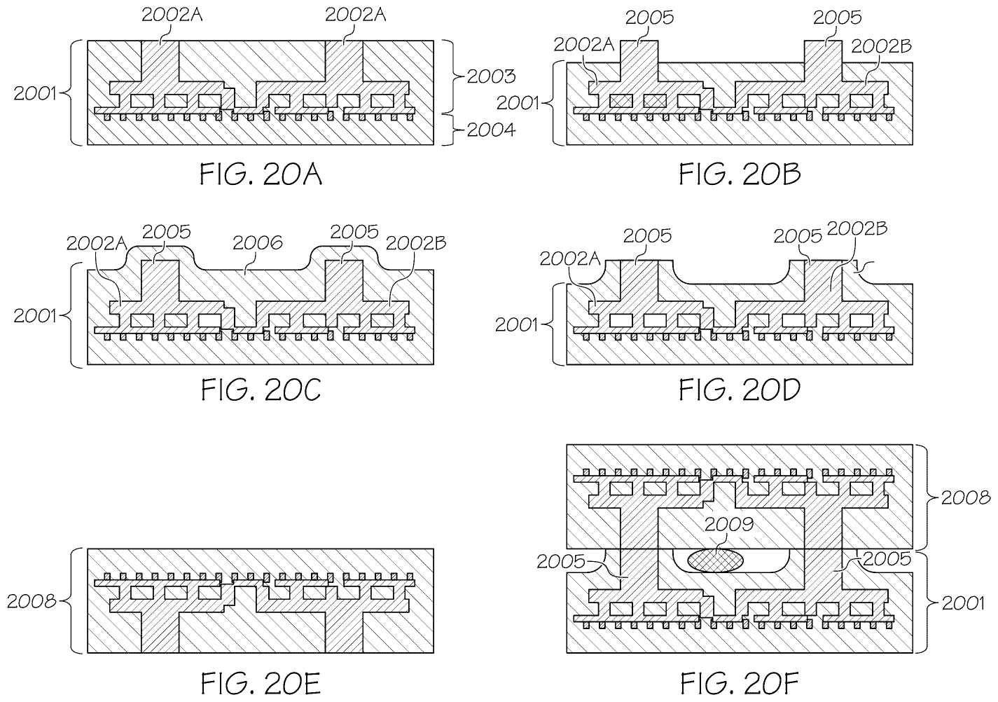

Referring now to FIG. 19, FIG. 19 is a flowchart of a method 1900 for performing direct bonding in accordance with an embodiment of the present disclosure. FIGS. 20A-20F depict the cross-sectional views for performing direct bonding using the steps described in FIG. 19 in accordance with an embodiment of the present disclosure.

Referring to FIG. 19, in conjunction with FIGS. 20A-20F, in step 1901 the oxide surrounding the top portion of substrates 2002A, 2002B is etched to reveal pillars 2005 as shown in FIGS. 20A-20B.

As shown in FIG. 20A, die 2001 includes two substrates 2002A, 2002B, which includes backend metal layers 2003 and a frontend 2004.

As shown in FIG. 20B, an oxide etch is performed on the structure of FIG. 20A resulting in revealing pillars 2005.

In step 1902, conformal oxide 2006 is deposited on the structure of FIG. 20B as shown in FIG. 20C.

In step 1903, an anisotropic oxide etch is performed resulting in the structure shown in FIG. 20D. Furthermore, as shown in FIG. 20D, as a result of the anisotropic oxide etch being performed, oxide spacers 20007 result around the metal pillars 2005.

In step 1904, direct bonding is performed on the structure of FIG. 20D with an unetched die as shown in FIGS. 20E and 20F. FIG. 20E illustrates an unetched die 2008 which is directly bonded to the structure shown in FIG. 20D resulting in the structure shown in FIG. 20F, which includes a particle 2009 in the gap between pillars 2005 of the structure of FIG. 20D.

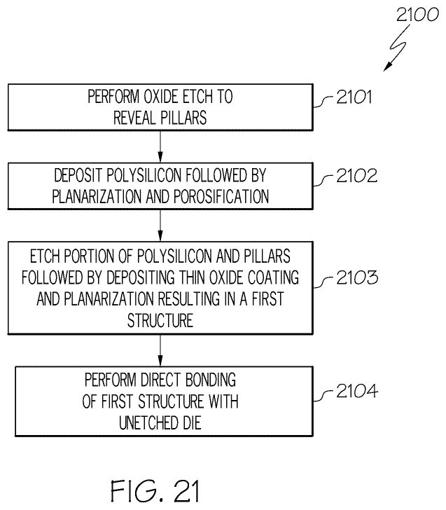

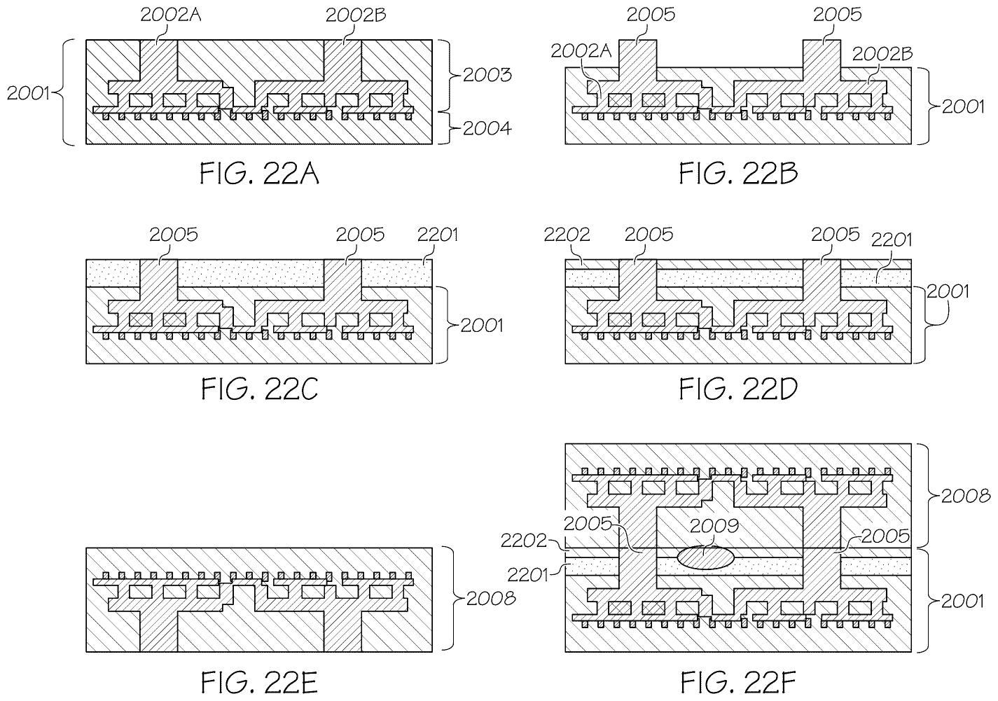

Referring now to FIG. 21, FIG. 21 is a flowchart of an alternative method 2100 for performing direct bonding in accordance with an embodiment of the present disclosure. FIGS. 22A-22F depict the cross-sectional views for performing direct bonding using the steps described in FIG. 21 in accordance with an embodiment of the present disclosure.

Referring to FIG. 21, in conjunction with FIGS. 22A-22F, in step 2101, the oxide surrounding the top portion of substrates 2002A, 2002B is etched to reveal pillars 2005 as shown in FIGS. 22A-22B.

As shown in FIG. 22A, die 2001 includes two substrates 2002A, 2002B, which includes backend metal layers 2003 and a frontend 2004.

As shown in FIG. 22B, an oxide etch is performed on the structure of FIG. 22A resulting in revealing pillars 2005.

In step 2102, polysilicon 2201 is deposited followed by planarization and porosification as shown in FIG. 22C.

In step 2103, a portion of polysilicon 2201 and pillars 2005 are etched followed by depositing a thin oxide coating 2202 which is followed by planarization as shown in FIG. 22D.

In step 2104, direct bonding is performed on the structure of FIG. 22D with an unetched die as shown in FIGS. 22E and 22F. FIG. 22E illustrates an unetched die 2008 which is directly bonded to the structure shown in FIG. 22D resulting in the structure shown in FIG. 22F, which includes a particle 2009 that has broken through thin oxide layer 2202 and become embedded in the porous layer (see 2201 and 2202 of FIG. 22F).

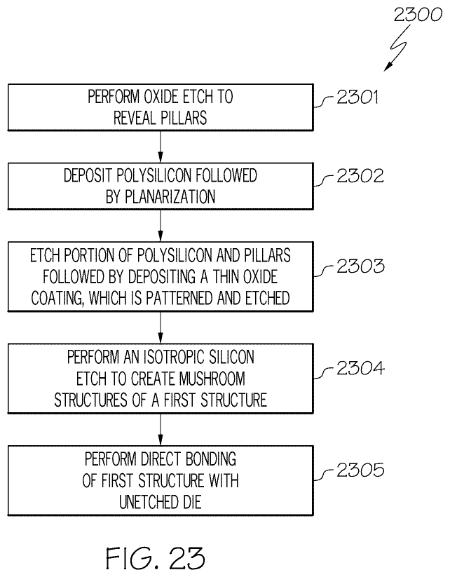

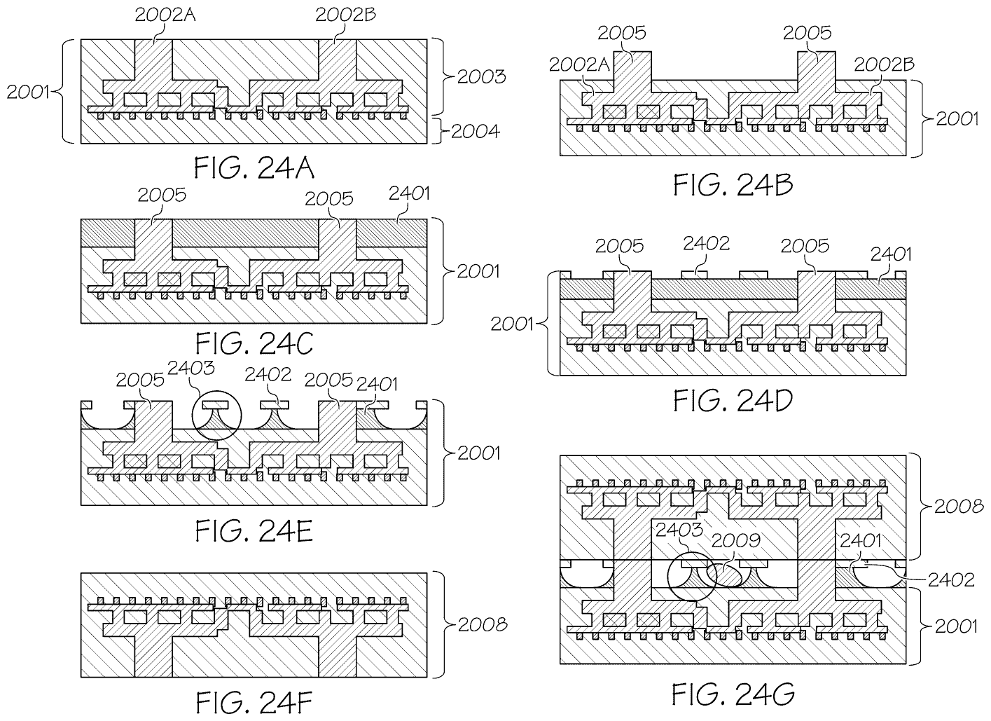

Referring now to FIG. 23, FIG. 23 is a flowchart of a further method 2300 for performing direct bonding in accordance with an embodiment of the present disclosure. FIGS. 24A-24G depict the cross-sectional views for performing direct bonding using the steps described in FIG. 23 in accordance with an embodiment of the present disclosure.

Referring to FIG. 23, in conjunction with FIGS. 24A-24G, in step 2301, the oxide surrounding the top portion of substrates 2002A, 2002B is etched to reveal pillars 2005 as shown in FIGS. 24A-24B.

As shown in FIG. 24A, die 2001 includes two substrates 2002A, 2002B, which includes backend metal layers 2003 and a frontend 2004.

As shown in FIG. 24B, an oxide etch is performed on the structure of FIG. 24A resulting in revealing pillars 2005.

In step 2302, polysilicon 2401 is deposited followed by planarization as shown in FIG. 24C.

In step 2303, a portion of polysilicon 2401 and pillars 2005 is etched followed by depositing a thin oxide coating 2402 which is patterned and etched as shown in FIG. 24D.

In step 2304, an isotropic silicon etch is performed to create mushroom structures 2403 as shown in FIG. 24E.

In step 2305, direct bonding is performed on the structure of FIG. 24E with an unetched die as shown in FIGS. 24F and 24G. FIG. 24F illustrates an unetched die 2008 which is directly bonded to the structure shown in FIG. 24E resulting in the structure shown in FIG. 24G, which includes a particle 2009 between mushroom structures 2403.

Referring to FIGS. 19, 20A-20F, 21, 22A-22F, 23 and 24A-24G, two substrates 2001, 2008 need to be bonded. Such substrates may be wafers, diced dies, etc. In one embodiment, an etch-back process is utilized to reduce the area of contact (during direct bonding) between the two substrates. Such a contact area reduction may make the direct bonding process more tolerant of particles. The particles would have a lower probability of landing at the bonding interface (compared to non-etched-back substrates). In one embodiment, the direct bonding is performed such that there is a first low-temperature oxide-to-oxide bonding step, followed by an anneal step to bond the metal connections. In one embodiment, only one of the two substrates 2001, 2008 to be direct bonded is subjected to the etch-back process, such as substrate 2001. In one embodiment, one of the substrates 2001, 2008 is an interposer and the other substrate is the die being bonded to the interposer. In one embodiment, only the interposer is subjected to the etch-back process. In one embodiment, the area of the etched-back regions is higher compared to the non-etched-back regions. The etch back process etches away the regions of oxide such that only metal pillars (e.g., pillars 2005) (which would get revealed as the oxide layer is etched back) and sparse regions of oxide remain after the etch back. The remaining oxide could be contiguous with the metal pillars (e.g., pillars 2005). In one embodiment, after the etch back, metal pillars (e.g., pillars 2005) with concentric and/or contiguous regions of oxide remain. In one embodiment, one or more of the following patterning techniques are utilized to perform this etch back process: photolithography, nanoimprint lithography, direct laser lithography and/or electron beam lithography followed by dry and/or wet etching. In one embodiment, a first oxide etch process is used to etch back all oxide (revealing metal pillars 2005). Subsequently, a conformal oxide coating (e.g., coating 2006), followed by an anisotropic oxide etch is performed to form spacers of oxide (e.g., spacers 2007) around the metal pillars (e.g., pillars 2005).

In one embodiment, one or both of the two substrates 2001, 2008 being direct bonded contain nano and/or micro features that undergo one or more of the following processes if a particle (e.g., particle 2009) is present at a certain location between the two substrates—the nano and/or microfeatures either pierce the particle and/or deterministically break locally.

In one embodiment, a porous layer (see 2201, 2202 of FIG. 22F) is created in the silicon around the metal pillars (e.g., pillars 2005). In one embodiment, this porous layer is created in silicon (using silicon porosification techniques, such as MACE, silicon anodization, electrochemical etching, etc.). In one embodiment, a porous layer (for instance, mesoporous aluminum oxide) is deposited in the etched back regions (in the process described above) and optionally planarized. In one embodiment, a thin uniform layer of silicon oxide is optionally deposited on the one or more porous layers described above.

In one embodiment, mushroom structures 2403 are created in the regions around the metal pillars (e.g., pillars 2005). These mushroom structures 2403 may have a base composed of silicon and a top composed of a different material (for instance, silicon oxide) that is suspended on the silicon base. The mushroom tops may deterministically collapse if loaded asymmetrically with a particle, such as particle 2009.

In one embodiment, die thinning is utilized to bring temperature hot spots closer to the heat sinks. For 2.5D integration, cooling solutions may interface with the die backside (e.g., die backside 711). For 3D ICs, cooling solutions may interface with both the die backside (e.g., die backside 711) and die frontside (for a die that is within a 3D stack).

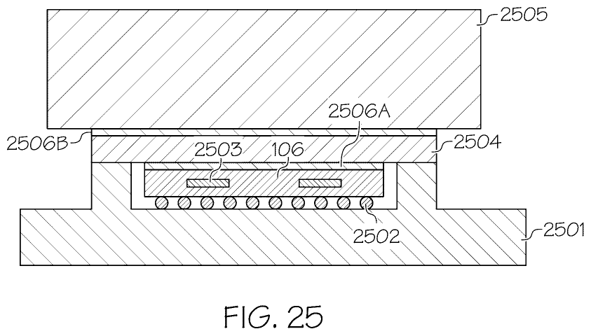

Referring now to FIG. 25, FIG. 25 illustrates a die cooling solution in accordance with an embodiment of the present disclosure.

As shown in FIG. 25, a die 106 is bonded on package substrate 2501 via adhesive 2502. Furthermore, as shown in FIG. 25, there are hot spots 2503 in die 106 which are sections which have cooled down more slowly than the surround material. Additionally, as shown in FIG. 25, a heat spreader layer (also referred to herein as simply “heat spreader”) 2504 is placed between die 106 and a fluidic cooling solution 2505 via thermal interface layer 1 (TIM1) 2506A and thermal interface layer 2 (TIM2) 2506B. Thermal interface layers 2506A-2506B may collectively or individually be referred to as thermal interface layers 2506 or thermal interface layer 2506, respectively. In one embodiment, heat spreader layer 2504 corresponds to a thermal packing component configured to move heat from a concentrated or high heat flux source to another area with a low heat flux source.

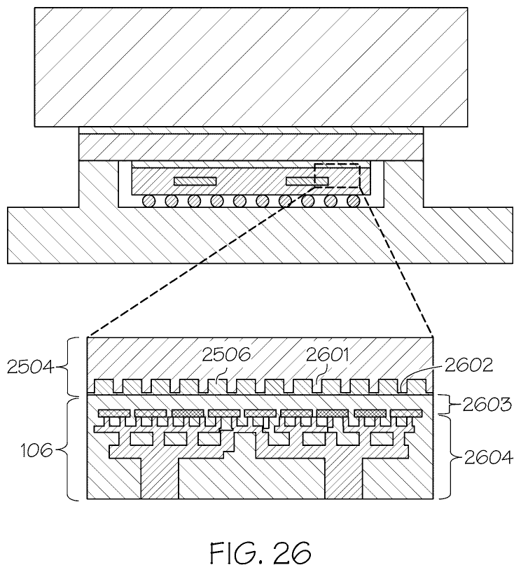

Referring now to FIG. 26, FIG. 26 is a cross-section of die 106 and heat spreader layer 2504 (e.g., diamond heat spreader) of FIG. 25 in accordance with an embodiment of the present disclosure.

As shown in FIG. 26, heat spreader layer 2504 includes pillars 2601. For example, pillars 2601 may be approximately 1 micrometer tall and 100 nm in diameter. In one embodiment, pillars 2601 correspond to 400 nm pitch pillars.

Furthermore, as shown in FIG. 26, heat spreader layer 2504 (e.g., diamond) may be attached to die 106 using a thin adhesive layer, a thin TIM layer (e.g., TIM layer 2506) or eutectic bonding (all represented by element 2602).

In one embodiment, a TIM layer 2506 is located in the gap between pillars 2601.

Furthermore, as shown in FIG. 26, the top portion of die 106 corresponds to a thinned die with a non-uniformly heated frontend 2603, where the darker shaded regions indicate hotter regions and the lighter shaded regions indicate colder regions.

Additionally, FIG. 26 illustrates the backend metal layer 2604, without significant joule heating.

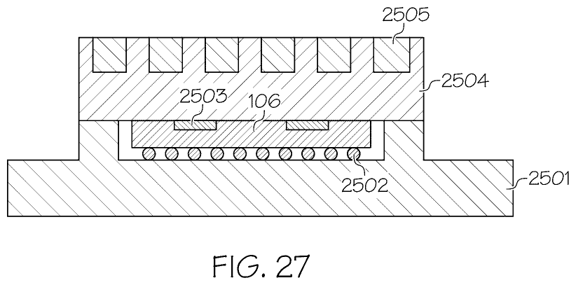

Referring to FIG. 27, FIG. 27 illustrates an alternative die cooling solution in accordance with an embodiment of the present disclosure.

The structure of FIG. 27 is the same as FIG. 25 except that fluidic cooling solution 2505 is now integrated into heat spreader 2504.

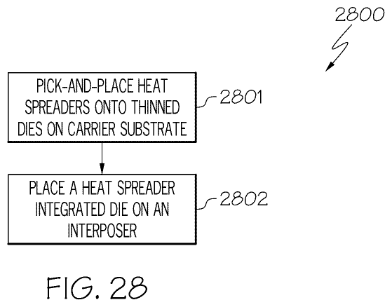

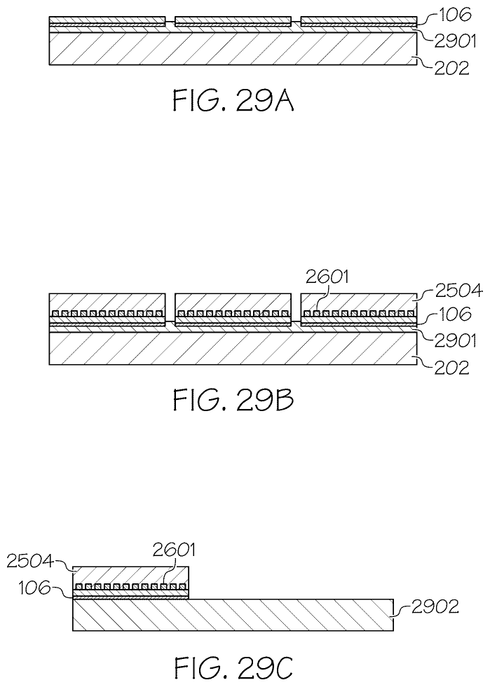

Referring now to FIG. 28, FIG. 28 is a flowchart of a method 2800 for integrating thinned dies with a heat spreader in accordance with an embodiment of the present disclosure. FIGS. 29A-29C depict the cross-sectional views for integrating thinned dies with a heat spreader using the steps described in FIG. 28 in accordance with an embodiment of the present disclosure.

Referring to FIG. 28, in conjunction with FIGS. 29A-29C, in step 2801, heat spreaders 2504 (e.g., diced and micro-machined diamond) are picked and placed onto thinned dies 106 on carrier substrate 202 as shown in FIGS. 29A-29B.

FIG. 29A illustrates thinned dies 106 are attached to carrier substrate 202, such as via adhesive 2901.

FIG. 29B illustrates the pick-and-place assembly of heat spreaders 2504 (e.g., diced and micro-machined diamond) onto thinned dies 106 on carrier substrate 202.

In step 2802, a heat spreader integrated die (heat spreader 2504 integrated with thinned die 106) is placed on an interposer 2902 (chip that can be used as a bridge or a conduit that allows electrical signals to pass through it and onto another element) as shown in FIG. 29C. A further discussion regarding FIGS. 25-28 and 29A-29C is provided below.

In one embodiment, die thermal hotspots 2503 are reduced using heat spreaders 2504, which may be composed of diamond, silicon carbide, boron nitride and other highly-thermally-conductive materials. In one embodiment, heat spreader 2504 is composed of multi-material stacks, for instance, epitaxially grown diamond on silicon and other multi-material stacks, such as diamond with a metal coating, silicon carbide with a metal coating, etc. In one embodiment, heat spreaders 2504 are stacked on top of one another. In one embodiment, heat spreaders 2504 are attached to die 106 to be cooled using a thermal interface material (TIM) 2506. In one embodiment, TIM 2506 is an adhesive, a thermally-conductive adhesive, a thermally-conductive polymer, a polymer dispersed with thermally-conductive nanoparticles, a metal, a metal alloy (for instance, solder, dymalloy, etc.) and/or a thermally-conductive dielectric. In one embodiment, heat spreader 2504 is composed of dymalloy (or other alloys of tunable thermal expansion and high thermal conductivity). In one embodiment, the composition of said alloys is such that the thermal expansion of the alloy matches the thermal expansion of die 106. In one embodiment, TIM 2506 is composed of a multi-layer stack of alloy layers of gradually varying thermal expansion with height, such that the bottom part of the layer matches the thermal expansion of die 106, and the top part matches the thermal expansion of heat spreader 2504 (or vice-versa, depending on die 106 and heat spreader configuration).

In one embodiment, the die backside (e.g., die backside 711) contains machined features. In one embodiment, the die backside (e.g., die backside 711) contains nanopillars arrays. In one embodiment, the die backside (e.g., die backside 711) contains nano-feature arrays. In one embodiment, the die backside (e.g., die backside 711) contains micro-feature arrays. Said arrays are created using MACE, anodization, silicon anodization, electrochemical etching and plasma etching, with optional patterning performed using photolithography, nanoimprint lithography, direct laser lithography, electron beam lithography, etc. In one embodiment, the die backside (e.g., die backside 711) contains black silicon. In one embodiment, die 106 is composed of silicon, such as silicon with epitaxially grown layers, such as GaN or other non-silicon substrates.

In one embodiment, the heat spreader frontside and/or backside contains machined features. In one embodiment, the heat spreader frontside and/or backside contains nanopillar arrays. In one embodiment, the heat spreader frontside and/or backside contains nano-feature arrays. In one embodiment, the heat spreader frontside and/or backside contains micro-feature arrays. In one embodiment, heat spreader 2504 contains micro-channels. In one embodiment, heat spreader 2504 contains micro-channels so as to integrate fluidic cooling solution 2505 in heat spreader 2504 itself. In one embodiment, said arrays are created using MACE, anodization, silicon anodization, electrochemical etching and/or plasma etching. In one embodiment, nickel-based etching is used for creating micro and/or nanostructures in diamond heat spreaders. In one embodiment, oxygen-plasma-based etching is used for creating micro and/or nanostructures in diamond heat spreaders. In one embodiment, an oxygen-plasma-resistant hard mask (for instance, silicon, polysilicon, silicon nitride, etc.) is utilized to etch diamond in specific regions. Optional patterning for the above etch steps are performed using photolithography, nanoimprint lithography, direct laser lithography, electron beam lithography, etc.

In one embodiment, heat spreader 2504 is attached to die 106 using one or more of the following methods: an adhesive, a thermally-conductive adhesive, thermally-conductive polymers, polymers dispersed with thermally-conductive nanoparticles, a metal, a metal alloy (for instance, solder, dymalloy, etc.), thermally-conductive dielectrics, eutectic bonding, hybrid bonding, fusion bonding, direct bonding, bonding with solder layer, flip chip bonding, etc. Optional interfacial fluid layers between die 106 and heat spreader 2504 are inkjetted, spin-coated, drop-casted, knife-edge coated, etc.

In one embodiment, heat spreader substrates (for instance, diamond) are diced on their own carrier substrate and picked-and-placed onto the die backside (e.g., die backside 711). In one embodiment, dicing is performed using mechanical, laser, plasma or chemical dicing.

In one embodiment, the nanostructures in heat spreader 2504 and/or the die backside (e.g., die backside 711) are tall and/or thin enough to accommodate (without substantial failure) differential thermal expansion between die 106 and heat spreader 2504 during chip operation. In one embodiment, the nanostructures in either or both of heat spreader 2504 and the die backside (e.g., die backside 711) are tall and/or thin enough to accommodate (without substantial failure) particles between die 106 and heat spreader 2504 during assembly of heat spreader 2504 onto die 106.

In one embodiment, the heat spreader substrate is assembled onto dies 106 prior to dicing, and dicing of the assembled heat spreader+die stack is performed using laser-based, mechanical, plasma-based and/or chemical dicing methods.

In one embodiment, heat spreader 2504 is used that matches the thermal expansion of die 106 and has a thermal conductivity that is higher compared to die 106.

In one embodiment, if multiple dies, with different thicknesses, need heat spreaders 2504, all could be connected to fluidic cooling solution 2505 using a multi-tiered adapter plate (which is made using copper, aluminum and other metals). In one embodiment, the adapter plate is computer numerical control (CNC) machined.

In one embodiment, heat spreaders 2504 are integrated onto existing chips that have been suitably decapped.

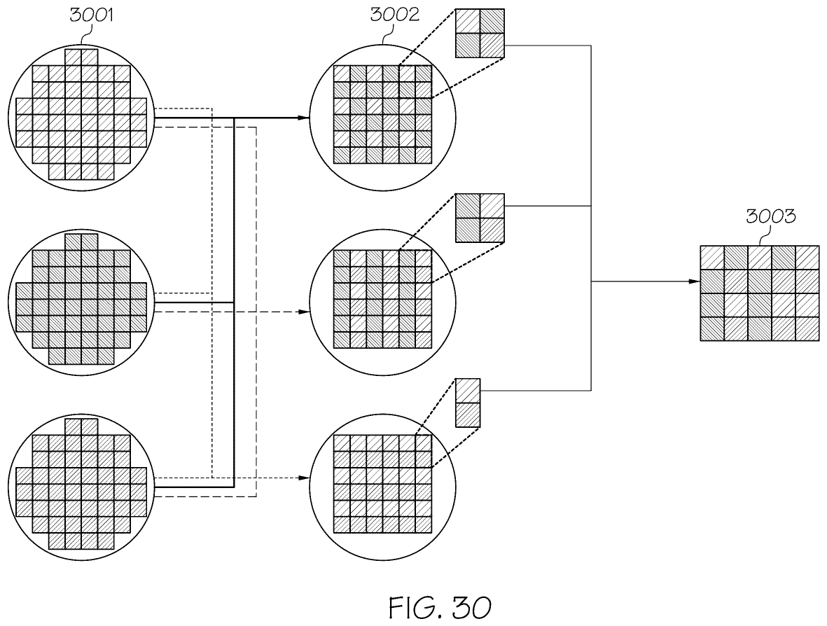

Referring now to FIG. 30, FIG. 30 illustrates an exemplary assembly of SiPs (system in package, which is a way of bundling two or more integrated circuits inside a single package) using hierarchical feedstock chips in accordance with an embodiment of the present disclosure.

As shown in FIG. 30, various level-one feedstocks (also referred to as feedstock chips, which are used to create other feedstock chips or SiPs) 3001 are picked-and-placed to create a level-two feedstock 3002. Furthermore, as shown in FIG. 30, level-two feedstocks 3002 are picked-and-placed to create an SiP 3003.

A further explanation regarding FIG. 30 is provided below.

In one embodiment, a tool for pick-and-place assembly is utilized to assemble dies 106 to create SiPs 3003 that are equal to, or larger, in size than of one or more of a 100 mm, 200 mm, 300 mm wafer, or a Gen 1, 2, 3, . . . 10 glass substrate. In one embodiment, the tool for pick-and-place assembly contains inkjets for adhesive dispensing. In one embodiment, the inkjets are mounted on a VPM (e.g., VPM 703). In one embodiment, the tool contains plasma heads for substrate cleaning and/or plasma activation. In one embodiment, the plasma heads are mounted on a VPM (e.g., VPM 703).

In one embodiment, one or more of feedstock chips (e.g., feedstock chips 3001), chosen from a fixed set of feedstock types, are used to assemble a SiP 3003 that is similar in one or more chosen metrics (such as chip power consumption, performance, area) to a monolithically fabricated SoC (System-on-Chip). For instance, a SiP that is 10 mm×10 mm in size, could be assembled using three types of feedstock chips (type A, B and C), each of which is 100 μm in size. In one embodiment, the same feedstock chips (for instance, type A, B and C) could be used to assemble SiPs with disparate functionality and design. In one embodiment, first-level feedstock chips 3001 are used to assemble second-level feedstock chips 3002. For instance, the three types of first-level feedstock chips 3001 A, B, C (each of which is 100 μm in size) are used to create 6 second-level feedstock chips 3002. In one embodiment, second-level feedstock chips 3002 are used to create third-level feedstock chips and so on. In one embodiment, first-level feedstock chips 3001 are all of the same size. In one embodiment, the assembly of said SiPs 3003 using said feedstock chips (e.g., second-level feedstock chips 3002) is performed using pick-and-place methods, such as the ones described above.

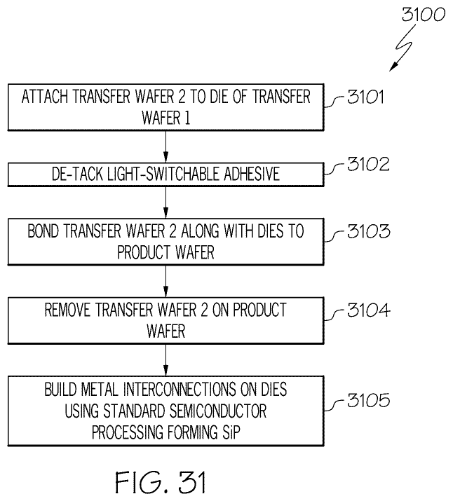

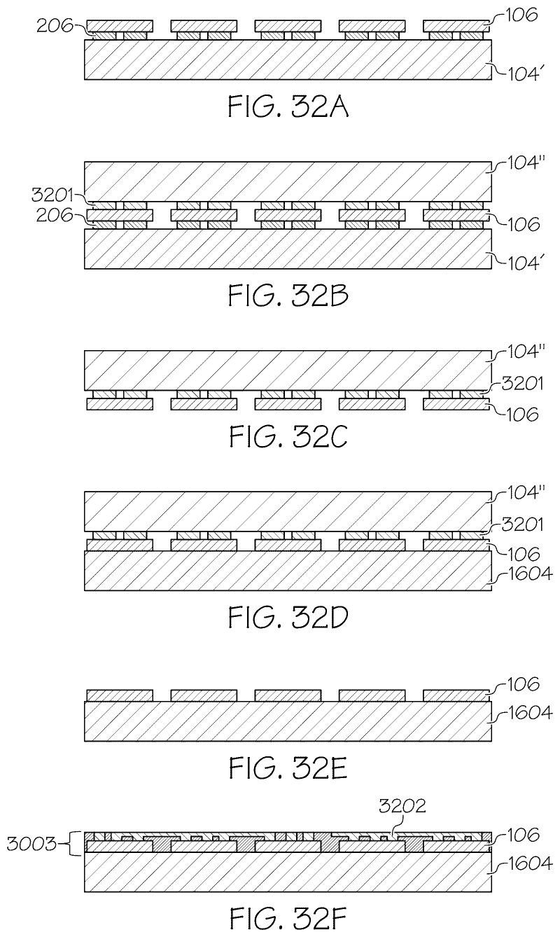

Referring now to FIG. 31, FIG. 31 is a flowchart of a method 3100 for fabricating SiPs in accordance with an embodiment of the present disclosure. FIGS. 32A-32F depict the cross-sectional views for fabricating SiPs using the steps described in FIG. 31 in accordance with an embodiment of the present disclosure.

Referring to FIG. 31, in conjunction with FIGS. 32A-32F, in step 3101, transfer wafer 2 104″ is attached to die 106 (facing upwards) of transfer wafer 1 104′ via an adhesive 3201 as shown in FIGS. 32A-32B.

FIG. 32A illustrates dies 106 (facing upwards) being attached to transfer wafer 1 104′ via light-switchable adhesive (LSA) 206.

As shown in FIG. 32B, a second transfer wafer (transfer wafer 2 104″) is then attached to dies 106 of transfer wafer 1 104′ using adhesive 3201.

In step 3102, light-switchable adhesive 206 is de-tacked, such as by using ultraviolet (UV) light, as shown in FIG. 32C.

In step 3103, second transfer wafer (transfer wafer 2 104″) along with dies 106 are bonded to product wafer 1604, such as via direct bonding as discussed herein, as shown in FIG. 32D.

In step 3104, transfer wafer 2 104″ is removed leaving dies 106 on product wafer 1604 as shown in FIG. 32E.

In step 3105, metal interconnections 3202 are built on dies 106 using standard semiconductor processing forming SiP 3003 as shown in FIG. 32F.

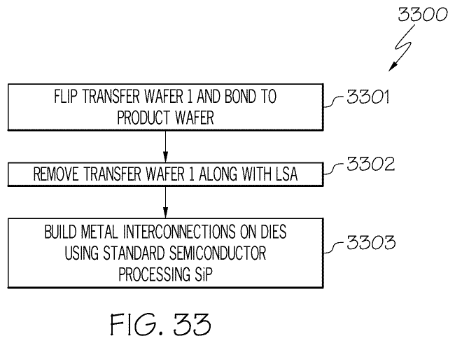

Referring now to FIG. 33, FIG. 33 is an alternative method for fabricating SiPs in accordance with an embodiment of the present disclosure. FIGS. 34A-34D depict the cross-sectional views for fabricating SiPs using the steps described in FIG. 33 in accordance with an embodiment of the present disclosure.

Referring to FIG. 33, in conjunction with FIGS. 34A-34D, in step 3301, transfer wafer 1 104′ is flipped (including dies 106 attached to transfer wafer 1 104′ via LSA 206) and bonded to product wafer 1604, such as via direct bonding as discussed herein, as shown in FIGS. 34A-34B.

FIG. 34A illustrates dies 106 (facing downwards) being attached to transfer wafer 1 104′ via light-switchable adhesive (LSA) 206.

FIG. 34B illustrates flipping transfer wafer 1 104′ which is bonded, such as via direct bonding as discussed herein, on product wafer 1604. As further shown in FIG. 34B, dies 106 are now facing upwards.

In step 3302, transfer wafer 1 104′ along with LSA 206 are removed as shown in FIG. 34C.

In step 3303, metal interconnections 3202 are built on dies 106 using standard semiconductor processing forming SiP 3003 as shown in FIG. 34D.

A more detailed discussion regarding FIGS. 31, 32A-32F, 33 and 34A-34D is provided below.

In one embodiment, dies 106 are picked-and-placed onto transfer wafer 104′ (“transfer wafer 1”). In one embodiment, dies 106 contain alignment marks on their front-side or back-side created, for instance, using sub-micrometer plasma dicing, or sub-micrometer MACE, or etched marks on the die back-side registered to the front-side. In one embodiment, the marks are moiré type, bob-in-box type, etc. In one embodiment, transfer wafer 1 104′ is transparent. In one embodiment, transfer wafer 1 104′ contains a set of alignment marks that are complementary to the die alignment marks. In one embodiment, a light-switchable adhesive (e.g., adhesive 206) is present between dies 106 and transfer wafer 104′. In one embodiment, LSA 206 (light-switchable adhesive), along with the complementary die and wafer marks, are used to precisely register dies 106 to transfer wafer 1 104′. In one embodiment, if dies 106 are facing down on transfer wafer 1 104′, a bonding step is performed onto product substrate 1604 in a wafer-to-wafer manner from transfer wafer 1 104′ to product 1604. If dies 106 on transfer wafer 1 104′ are facing up, dies 106 could be transferred to an another transfer wafer 104″ (“transfer wafer 2”). Subsequently, a bonding step is performed onto a product substrate 1604 in a wafer-to-wafer manner from transfer wafer 2 104″ to product wafer 1604. In one embodiment, the bonding is one or more of the following types: eutectic bonding, thermocompression bonding, direct bonding, hybrid bonding, anodic bonding, fusion bonding and bonding using a thin layer of dispensed adhesive. In one embodiment, product wafer 1604 has nanopillar arrays. In one embodiment, the nanopillar arrays are sparse (for instance, 1% to 4% of the substrate surface area), such that the bonding occurs in sparse locations, reducing the likelihood of particle hotspots. In one embodiment, metal interconnections between the assembled die 106 on product wafer 1604 are made using conventional semiconductor fabrication processes (metal deposition, dielectric deposition, planarization, etching, lithography, etc.).

In one embodiment, precision die thinning is performed on dies 106 that rest face down (with metal structures facing down and bulk silicon facing up) on carrier wafer 202 (for instance, a transparent carrier wafer or a glass carrier wafer), an intermediate wafer (for instance, a transfer wafer 104), tape frame 301, source wafer 105, product wafer 1604, etc.

In one embodiment, precision die thinning (PDT) is performed using methods that utilize adaptively-inkjetted resist drops and/or using plasma etching techniques (for which the etch rates are locally controlled using thermal actuators) as described in U.S. Pat. No. 8,394,282, U.S. patent application Ser. No. 15/457,283, U.S. Pat. Nos. 9,415,418, 9,718,096, U.S. patent application Ser. No. 17/413,523, International Application No. PCT/US2021/024250, EP17767252.4, U.S. patent application Ser. No. 16/322,882, International Application No. PCT/US2021/019732, EP14767171.3, U.S. Patent Application Ser. No. 63/336,901 and U.S. Patent Application Ser. No. 63/314,725, all of which are incorporated by reference herein in their entirety.

In one embodiment, PDT enables die bonding and heterogeneous integration applications, where a die is to be assembled onto two or more pre-existing die (on a product wafer, reconstituted wafer, etc.), and also straddles said two or more die (each of which could have a unique thickness). PDT would reduce the thickness variation of the pre-existing dies to an extent that the top straddling die could make high-quality contact with the pre-existing dies.

In one embodiment, PDT enables die on die stacking, where low thickness variation of the bonded die is required for circuit performance reasons (for instance, for improved timing). For instance, lower thickness variation could lead to lower variation in the height of through silicon vias (TSVs) thereby improving the variation in signal propagation times across the product (for instance, a system in package).

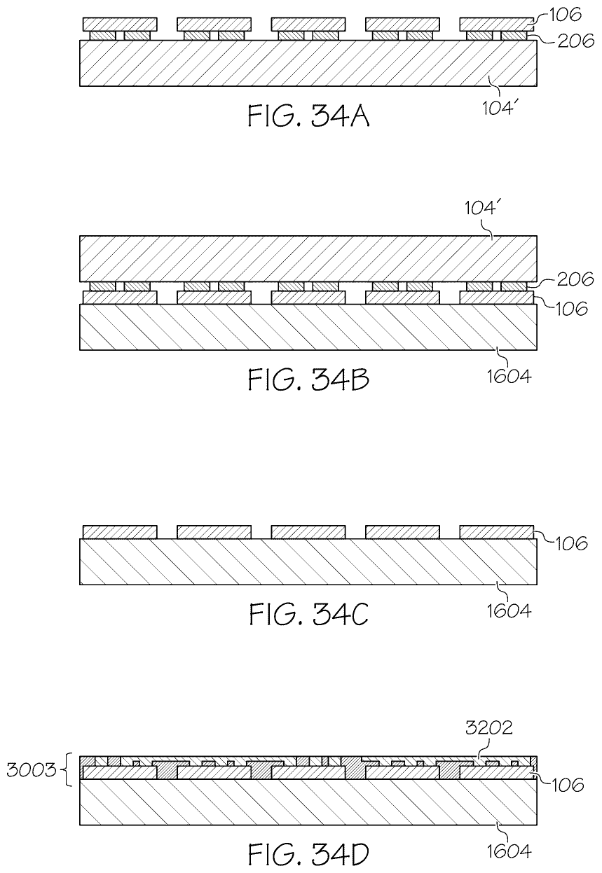

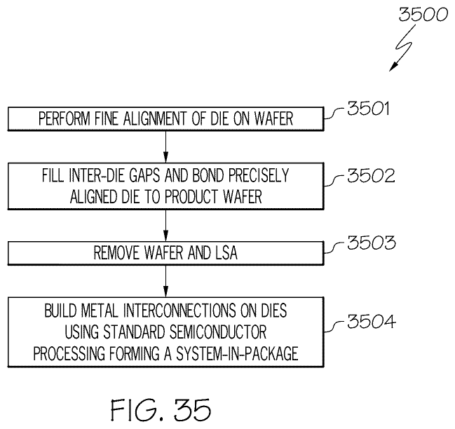

Referring now to FIG. 35, FIG. 35 is a flowchart of a method 3500 for performing heterogeneous integration in accordance with an embodiment of the present disclosure. FIGS. 36A-36D depict the cross-sectional views for performing heterogeneous integration using the steps described in FIG. 35 in accordance with an embodiment of the present disclosure.

Referring to FIG. 35, in conjunction with FIGS. 36A-36D, in step 3501, fine alignment of die 106 on wafer 3601 (e.g., transfer wafer 104, intermediate wafer) is performed as shown in FIGS. 36A-36B.

FIG. 36A illustrates die 106 (facing downwards) that are coarsely aligned on wafer 3601 (e.g., transfer wafer 104, intermediate wafer). As further shown in FIG. 36A, die 106 are attached to wafer 3601 via LSA 206 or another type of adhesive.

In one embodiment, the structure shown in FIG. 36A is obtained from die 106 from source wafers 105 on tape frame 301. Dies 106 are facing up, have optionally been plasma activated, and optionally spin-coated with a thin film of water. In one embodiment, a die flip and coarse placement is performed by the chip shooter at high-throughput (e.g., 30,000 die per hour). Alternatively, tape frame 301 is mounted upside down and die 106 are picked down using a pick-and-place tool with a VPM 703 and transferred to short-stroke stage array 1703 and finally placed onto transfer wafer 104.

In one embodiment, fine alignment of die 106 on wafer 3601 is performed using LSA alignment to achieve sub-10 nm, sub-25 nm, sub-50 nm, sub-100 nm or sub-200 nm assembly precision.

As shown in FIG. 36B, dies 106 are now precisely aligned in comparison to the positioning of dies 106 as shown in FIG. 36A.

In step 3502, the inter-die gaps are filled along with bonding the precisely aligned die 106 to product wafer 1604 as shown in FIG. 36C.

In one embodiment, such bonding is performed using direct bonding as discussed herein. In one embodiment, direct bonding is performed using standard wafer-to-wafer fusion bonders.

It is noted that PDT enables step 3502, since without PDT, adjacent dies 106 could have thickness variation of as much as 5 μm, which would likely prevent wafer-to-wafer fusion bonding near the die boundaries.

In step 3503, wafer 3601 (e.g., transfer wafer 104, intermediate wafer) and LSA 206 are removed as shown in FIG. 36D.

In step 3504, metal interconnections 3601 are built on dies 106 using standard semiconductor processing forming a system-in-package 3003 as shown in FIG. 36D.

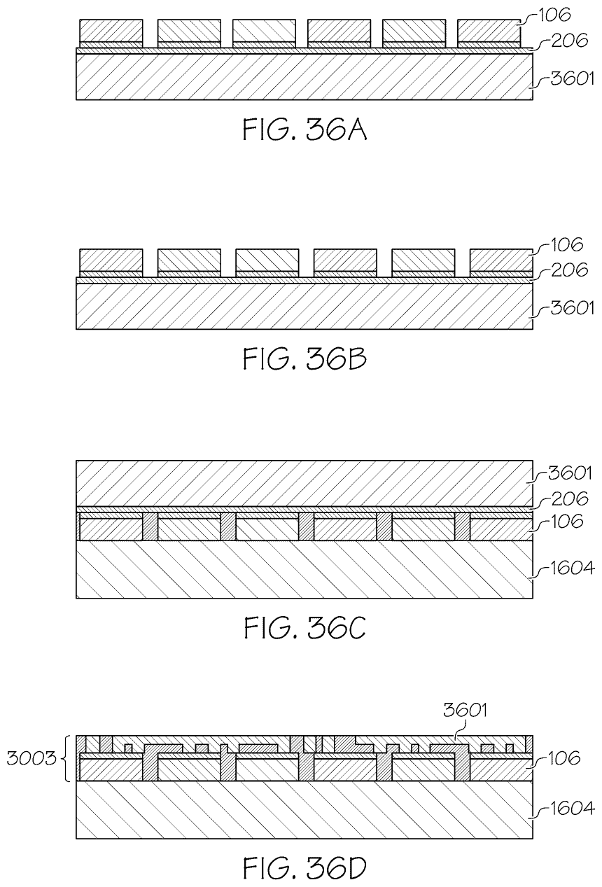

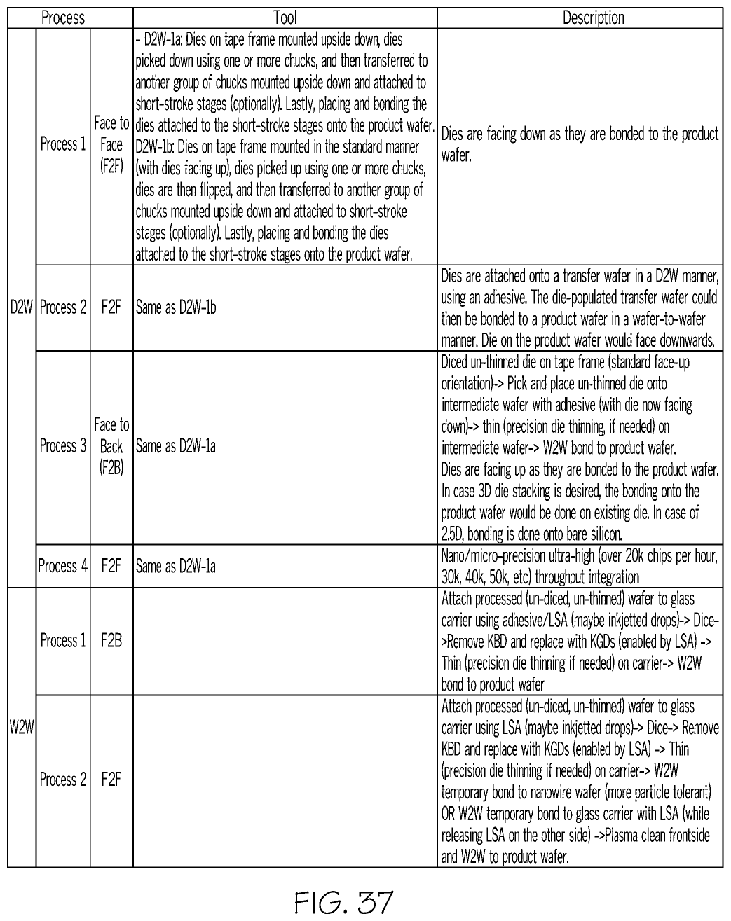

Details regarding the heterogeneous integration process are shown in FIG. 37 in accordance with an embodiment of the present disclosure.

Referring now to FIGS. 38A-38B, FIGS. 38A-38B illustrate a wafer-to-wafer bonding method in accordance with an embodiment of the present disclosure.

As shown in FIG. 38A, FIG. 38A illustrates dies 106 on tape frame 301, where tape frame 301 is mounted upside down. Furthermore, as shown in FIG. 38A, some of the die 106 have been picked such as shown by element 3801.

In one embodiment, such picked die are placed on a die chuck (wafer-scale die chuck) 3802. In one embodiment, all or a portion (e.g., half, quarter, eighth, etc.) of dies 106 from tape frame 301 are picked and placed on die chuck 3802 at a single time. In one embodiment, the picked dies are distributed on die chuck 3802 in a checkerboard manner. In one embodiment, die chuck 3802 has individually actuatable chucking regions to pick only known good dies.

In one embodiment, die chuck 3802 is mounted on a stage. After picking up known good dies from tape frame 301, it moves underneath short-stroke stage array 1703 and transfers all the picked dies onto short-stroke stages 1703 as shown in FIG. 38B.

FIG. 38B illustrates nanoprecise short-stroke stages 1703 (with integrated chucks) permanently or semi-permanently attached to a thermo-mechanically stable frame (short-stroke stage frame) 3803. In the embodiment in which short-stroke stages 1703 are semi-permanently attached to frame 3803, a pitch varying mechanism is utilized to rearrange the position of short-stroke stages 1703.

Furthermore, in one embodiment, as shown in FIG. 38B, product wafer 1604 includes a pre-existing layer of circuits (e.g., DRAM logic, SRAM, flash memory, imager circuits, etc.) on dies 3804.

In one embodiment, picked dies 106 are bonded onto product wafer 1604. In one embodiment, the bonding is performed in an in-liquid manner so as to achieve an overlay precision of sub-10 nm, sub-25 nm, sub-50 nm, sub-00 nm, sub-200 nm and sub-500 nm. Such methods have been discussed herein.

In one embodiment, for multiply-stacked memory applications (e.g., high-bandwidth memory (HBM)), the size of dies 106, 3804 being bonded to each other are substantially the same.

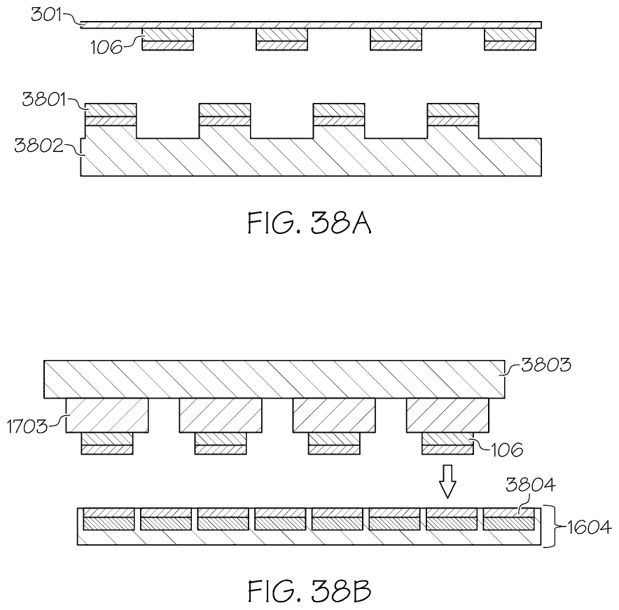

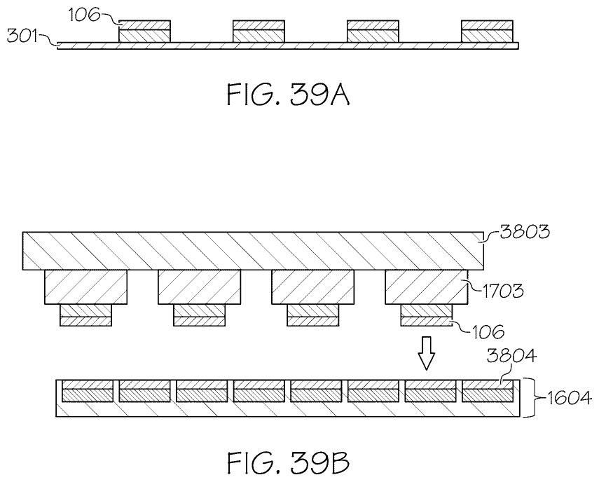

Referring now to FIGS. 39A-39B, FIGS. 39A-39B illustrate an alternative wafer-to-wafer bonding method in accordance with an embodiment of the present disclosure.

As shown in FIG. 39A, FIG. 39A illustrates dies 106 on tape frame 301, where tape frame 301 is mounted in a regular manner with dies 106 facing up.

In one embodiment, short-stroke stage array 1703 directly picks dies 106 from tape frame 301 as shown in FIG. 39B.

FIG. 39B illustrates nanoprecise short-stroke stages 1703 (with integrated chucks) permanently or semi-permanently attached to a thermo-mechanically stable frame (short-stroke stage frame) 3803. In the embodiment in which short-stroke stages 1703 are semi-permanently attached to frame 3803, a pitch varying mechanism is utilized to rearrange the position of short-stroke stages 1703.

Furthermore, in one embodiment, as shown in FIG. 39B, product wafer 1604 includes a pre-existing layer of circuits (e.g., DRAM logic, SRAM, flash memory, imager circuits, etc.) on dies 3804.

In one embodiment, picked dies 106 are bonded onto product wafer 1604. In one embodiment, the bonding is performed in an in-liquid manner so as to achieve an overlay precision of sub-10 nm, sub-25 nm, sub-50 nm, sub-00 nm, sub-200 nm and sub-500 nm. Such methods have been discussed herein.

In one embodiment, for multiply-stacked memory applications (e.g., high-bandwidth memory (HBM)), the size of dies 106, 3804 being bonded to each other are substantially the same.

Referring to FIGS. 38A-38B and 39A-39B, in one embodiment, the type of bonding performed includes fusion bonding, hybrid bonding, bump bonding, anodic bonding, etc. In one embodiment, the bonding utilizes fluids, such as water, LSA or other adhesives, to improve the overlay precision of bonding as described above. Short-stroke stages 1703 are based on one or more of the following actuation principles: piezoelectric actuation, electromagnetic actuation (such as voice coils), thermal actuation, etc.

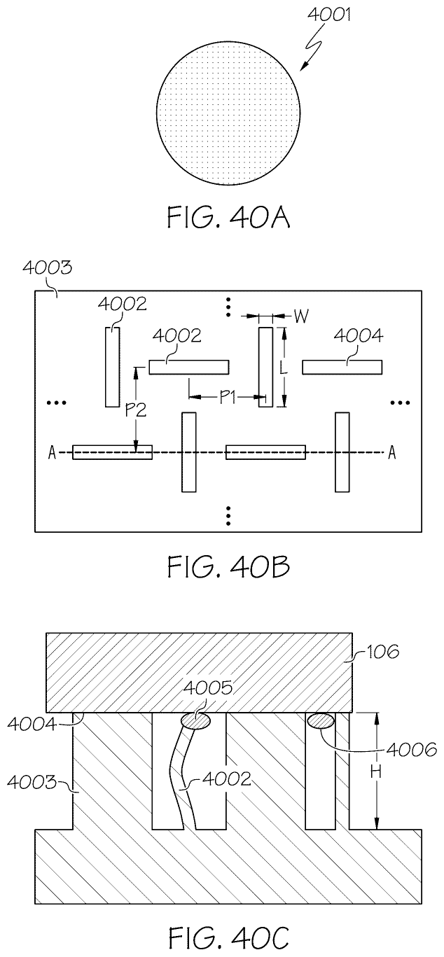

Referring now to FIGS. 40A-40C, FIGS. 40A-40C illustrate a nano/micropatterned support wafer in accordance with an embodiment of the present disclosure.

FIG. 40A illustrates a top view of a nano/micropatterned support wafer 4001. An expanded view of the top view of nano/micropatterned support wafer 4001 is shown in FIG. 40B.

As shown in FIG. 40B, micro/nanofabricated pins 4002 are located on the support substrate 4003. Furthermore, as shown in FIG. 40B, the shown arrangement (see element 4004) of pins 4002 provides mechanical stiffness in both the x and y directions.

A cross-section at AA (see FIG. 40B) is shown in FIG. 40C. In particular, FIG. 40C illustrates the interface 4004 between die 106 and support wafer 4003. In one embodiment, interface 4004 is a fusion bonded interface (between two oxide surfaces) or an adhesive bonded interface.

Furthermore, FIG. 40C illustrates a particle 4005 on top of pin 4002, which has buckled due to the concentrated load. Additionally, FIG. 40C illustrates an exemplary particle 4006 between the support wafer pins 4002.

In one embodiment, pins 4002 are optimized to satisfy the following constraints: (1) ability to support dice in the x, y and z directions, while also being able to handle thermo-mechanical loads during die processing, such as during polishing, chemical mechanical polishing, grinding, dicing, etching, lithography, material deposition, coating, etc.; (2) ability of individual pins to buckle/bend due to concentrated loads, for instance, when a particle is presented between a pin and the die; and (3) a sparse enough pin distribution such that most particles at the die-wafer interface fall in the gaps between the pins and where the contact area between the pins and the die could be 0.1%, 0.5%, 1%, 2% or 5% of the die area.

A table showing example measurements (W corresponds to width, L corresponds to length, H corresponds to height, P1 corresponds to the distance depicted in FIG. 40B and P2 corresponds to the distance depicted in FIG. 40B) of pins 4002 is provided below:

| Example | W | L | H | P1 | P2 |
|---|---|---|---|---|---|
| 1 | 50 nm | 100 nm | 1 μm | 1 μm | 1 μm |
| 2 | 100 nm | 500 nm | 1 μm | 1 μm | 10 μm |
| Mix-and-Match | 20 nm, 50 nm, | 100 nm, 500 nm, | 500 nm, 1 μm, 2 | 200 nm, 500 nm, | 200 nm, 500 nm, |
| Examples | 100 nm, 250 nm, | 1 μm, 2 μm, 5 | μm, 5 μm, 10 | 1 μm, 5 μm, 10 | 1 μm, 5 μm, 10 |
| | 500 nm, . . . | μm, 10 μm, . . . | μm, 50 μm, . . . | μm, 20 μm, . . . | μm, 20 μm, . . . |

In one embodiment, a nano and/or micropatterned support wafer 4001 is used as a replacement for the temporary wafers and/or carrier wafers 202 and/or transfer wafers 104 and/or product wafers 1604 discussed herein. In one embodiment, pins 4002 are designed so as to buckle and/or bend if a particle (e.g., particle 4005) is present at interface 4004 between pin 4002 and die 106 on top. Design optimization techniques, such as genetic algorithm (or other heuristic algorithm) based constrained optimization, may be used to arrive at optimal geometries for the pins. More details regarding the design of such pins can be found in Ajay et al., “Methods for Nano-Precise Overlay in Advanced in Pick-and-Place Assembly,” Dissertation, August 2019, which is incorporated by reference herein in its entirety. In one embodiment, wafer 4001 is composed of one or more of silicon, silicon dioxide, aluminum oxide, sapphire, metals, metal oxides, polymers, PTFE, fluoropolymers, carbon, boron, etc.

In one embodiment, wafer 4001 is fabricated using patterning techniques, such as particle lithography (PL), nanoimprint lithography (NIL), etc. and deep etch techniques, such as metal assisted chemical etching, deep reactive ion etch (DRIE), reactive ion etch (RIE), crystallographic etching, etc.

In one embodiment, wafer 4001 is attached to a die (e.g., die 106) using one or more of the following methods: fusion bonding (oxide-oxide), hybrid bonding (oxide-oxide, metal-metal), direct bonding, anodic bonding and covalent bonding. In the embodiment in which direct bonding/fusion bonding/hybrid bonding is utilized, a thin layer of water may be utilized at the interface between die 106 and the support wafer pins 4002. In one embodiment, adhesive is dispensed on the surface of die 106 being attached to support wafer 4001 (using inkjetting, spin-coating, dip-coating, slot-die coating, etc.) or on support wafer 4001 itself. In one embodiment, the adhesive is dispensed on the tops of support wafer pins 4002 using dip coating, vapor condensation, etc. In one embodiment, the adhesive is dispensed on the surface of die 106 being attached to support wafer 4001 or on support wafer 4001 itself. In one embodiment, the adhesive is dispensed on the tops of support-wafer-pins 4002 using dip-coating, inkjetting, etc.

In one embodiment, support wafer 4001 is separated from the dice it was supporting, using (a) HF, vapor HF (this is in case direct/fusion/hybrid bonding was the method of attachment), (b) thermal slide (this is in case a suitable low-glass-transition-temperature adhesive is utilized) and/or (c) UV-detacking (in case a UV-detacking material, such as a light-switchable adhesive, is utilized). In case a vapor-based separation method is utilized (for instance, using vapor HF), a sparse distribution of pins would permit rapid separation compared to the case in which there were no pins (regular support wafer). Additionally, the width (W) and/or length (L) as shown in the above table could be small (e.g., 50 nm, 100 nm, 200 nm) so as to permit rapid separation of pins 4002 from the bonded die 106 (at a nominal etch rate of ˜60 nm/min).

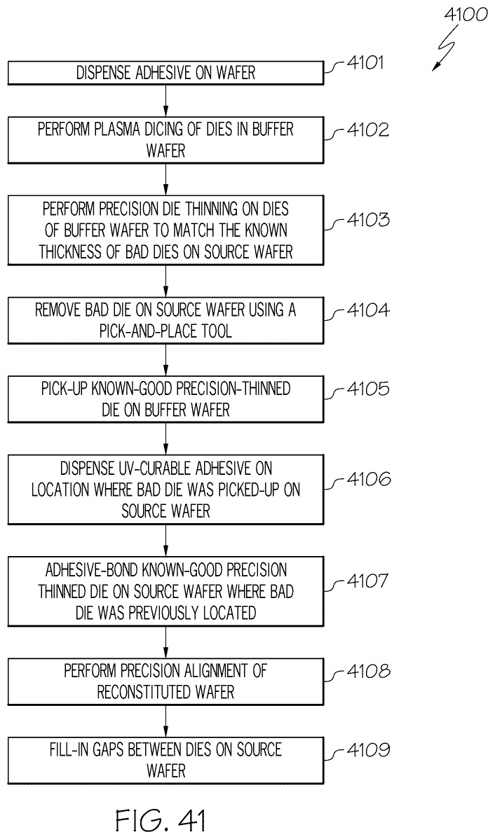

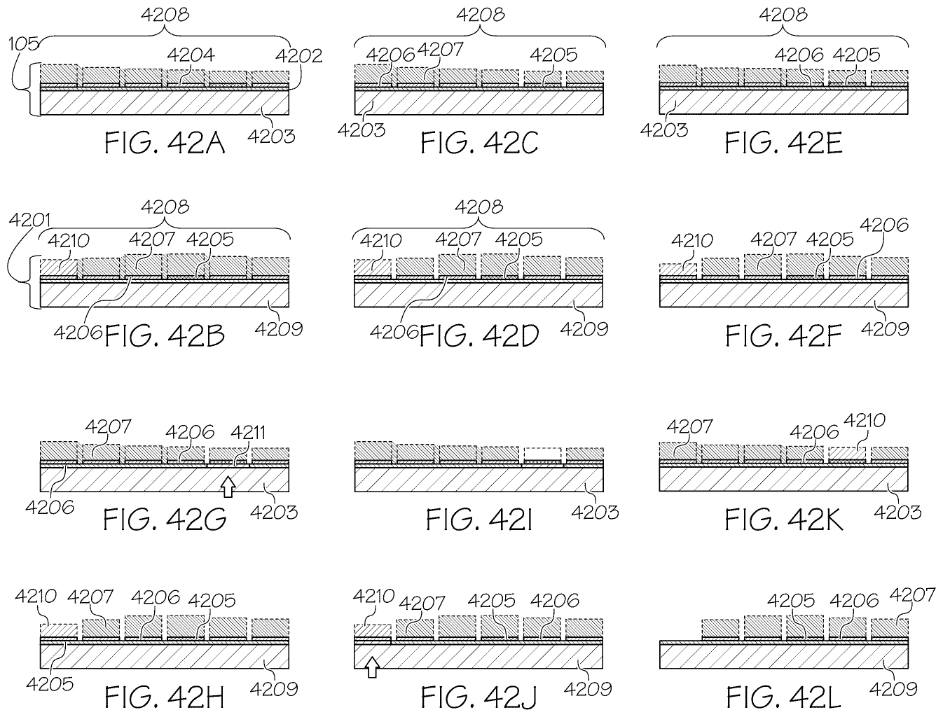

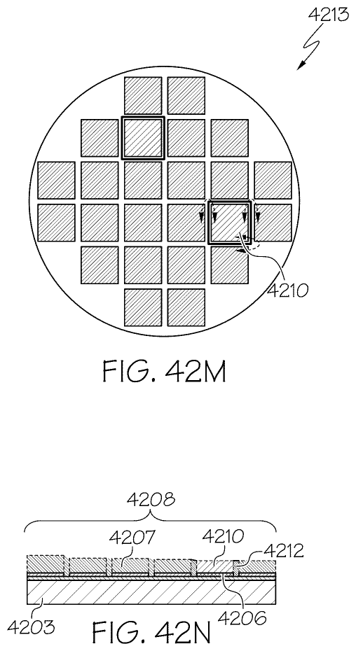

Referring now to FIG. 41, FIG. 41 is a flowchart of a method 4100 for creating a reconstituted wafer for face to back (F2B) bonding in accordance with an embodiment of the present disclosure. A reconstituted wafer, as used herein, refers to a new wafer upon which the dies are placed on such a new wafer using a pick-and-place system. FIGS. 42A-42N depict the cross-sectional views for creating a reconstituted wafer for face to back (F2B) bonding using the steps described in FIG. 41 in accordance with an embodiment of the present disclosure. Source wafer 105 is described using FIGS. 42A, 42C, 42E, 42G, 42H, 42I, 42K, 42M and 42N. Buffer wafer 4201 is described using FIGS. 42B, 42D, 42F, 42H, 42J and 42L.

Referring to FIG. 41, in conjunction with FIGS. 42A-42N, in step 4101, adhesive 4202 (e.g., LSA, resist, NIL resist, etc.) is dispensed (e.g., spin-coated, inkjetted, etc.) on wafer 4203 (e.g., transfer wafer 104, carrier wafer 202) as shown in FIG. 42A.

Furthermore, as shown in FIG. 42A, metal layers 4204 are facing towards wafer 4202.

Additionally, as shown in FIG. 42C, source wafer 105 includes a bad die 4205 plasma diced. The remaining dies are good dies 4206. Dies, including bad dies 4205 and good dies 4026, may collectively be referred to herein as dies 4208. Regions 4207 are un-diced kerf regions.

In step 4102, plasma dicing of dies 4208 in buffer wafer 4201 is performed as shown in FIGS. 42B and 42D.

Referring to FIG. 42B, buffer wafer 4201 includes dies 4208 on wafer 4209 (e.g., transfer wafer 104, carrier wafer 202), where dies 4028 include a bad die 4205 as well as good dies 4206. Furthermore, FIG. 42B illustrates that dies 4208 are slighter larger in mean thickness compared to dies 4208 on wafer 4203 (e.g., by 500 nm, 1 μm, 2 μm, etc.).

Furthermore, FIG. 42D illustrates the plasma dicing of dies 4208 in buffer wafer 4201.

Additionally, FIGS. 42B and 42D illustrate a die 4210 to replace bad die 4205 on wafer 4203.

In step 4103, precision die thinning is performed on dies 4208 of buffer wafer 4201 to match the known thickness of bad dies 4205 on wafer 4203 as shown in FIGS. 42E, 42F. In one embodiment, such precision die thinning is performed with sub-50 nm rms error.

For example, dies 4028 on buffer wafer 4201, such as die 4210, is thinned to match the known thickness of bad die 4205 on wafer 4203 as shown in FIGS. 42E, 42F.

In step 4104, bad die 4205 on wafer 4203 is removed using a pick-and-place tool utilizing liquifying adhesive 4211 (e.g., UV irradiation from chuck-side) as illustrated in FIG. 42G. As shown in FIG. 42H, there is no change on buffer 4201 at this moment in time.

In step 4105, known-good precision-thinned die, such as die 4210, on buffer wafer 4201 is picked-up using a pick-and-place tool utilizing liquifying adhesive 4211 as shown in FIGS. 42J and 42L.

In step 4106, UV-curable adhesive is dispensed on the location where bad die 4205 was picked-up on wafer 4203 as shown in FIG. 42I.

In step 4107, known-good precision thinned die, such as die 4210, is adhesive-bonded on wafer 4203 where bad die 4205 was previously located as shown in FIG. 42K forming a reconstituted wafer.

In step 4108, precision alignment (e.g., using in-liquid-enabled alignment architectures) is performed on the reconstituted wafer 4213 as shown in FIG. 42M. As shown in FIG. 42M, the good die 4210 that replaced the bad die 4205 on wafer 4203 has been aligned with respect to the neighboring die.

In one embodiment, alignment marks on adjacent die corners are used for measurement of the alignment of the new good die with respect to the wafer grid. In such an embodiment, alignment marks on wafer 4203 (e.g., carrier wafer 202) would not be required.

In step 4109, gaps between dies 4202 on wafer 4203 are then filled using material 4212 as shown in FIG. 42N. Planarization (e.g., chemical mechanical polishing) after filling the gaps between dies 4208 may also be performed.

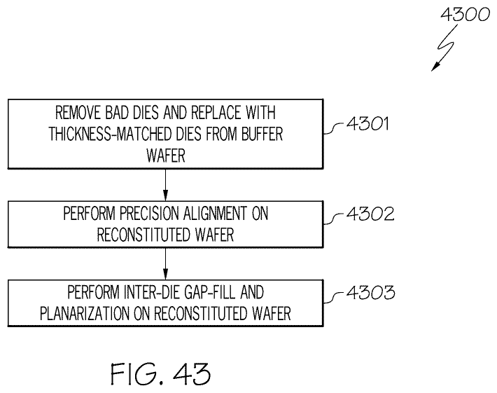

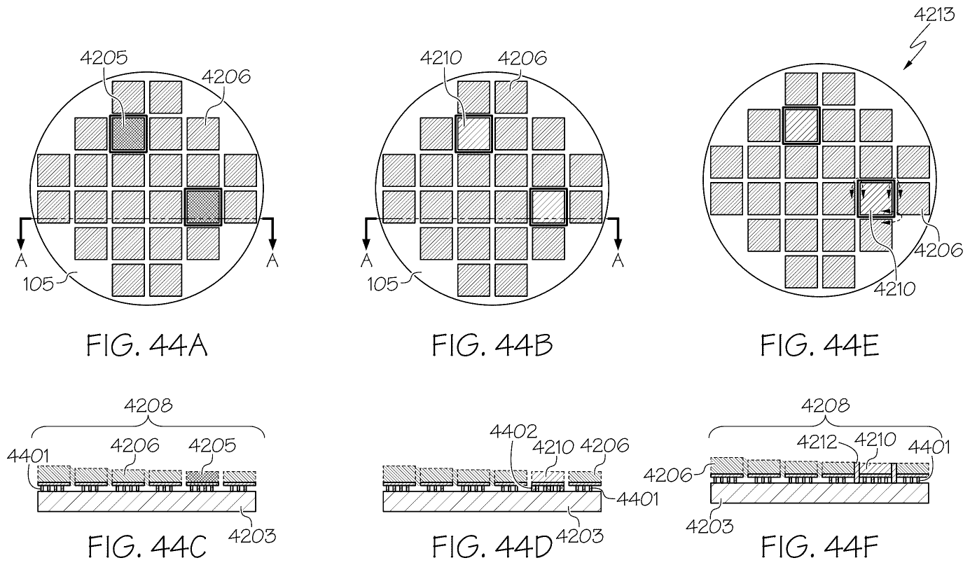

Referring now to FIG. 43, FIG. 43 is a flowchart of an alternative method 4300 for creating a reconstituted wafer for face to back (F2B) bonding in accordance with an embodiment of the present disclosure. FIGS. 44A-44F depict the cross-sectional views for creating a reconstituted wafer for face to back (F2B) bonding using the steps described in FIG. 43 in accordance with an embodiment of the present disclosure.

Referring to FIG. 43, in conjunction with FIGS. 44A-44F, in step 4301, bad dies 4205 are removed using a precise pick-and-place tool (enabled by nanowire temporary fusion bonding/debonding) and replaced with thickness-matched dies 4210 from buffer wafer 4201 as shown in FIGS. 44A, 44B.

FIG. 44A illustrates a top view of source wafer 105 with the bad die 4205 plasma diced. The remaining dies on source wafer 105 are good dies 4206.

Referring now to FIG. 44C, FIG. 44C illustrates a view of the cross-section of AA of FIG. 44A. As shown in FIG. 44C, wafer 4203 (e.g., silicon carrier wafer) includes nanowires 4401 that are temporarily fusion bonded to wafer 4203. In one embodiment, the regions near the edge of each die 4208 (good dies 4206, bad die 4205) is free of nanowires. In such an embodiment, bad dies, such as bad die 4205, is easier to be de-tacked.

Referring now to FIG. 44D, FIG. 44D illustrates a view of the cross-section of AA of FIG. 44B. As shown in FIG. 44D, water 4402 is inkjetted in discrete regions underneath the replaced die (underneath thickness-matched die 4210 that replaced bad die 4205) for in-liquid align and rapid evaporation. In one embodiment, water 4402 is confined within the islands (discussed further below) using capillary confinement or using dense walls of nanowires near the periphery of the islands.

In step 4302, precision alignment is performed on reconstituted wafer 4213 as shown in FIG. 44E. For example, precision alignment is performed using in-liquid enabled alignment architectures.

In step 4303, inter-die gap-fill and planarization are performed on reconstituted wafer 4213 as shown in FIG. 44F. For example, material 4212 is filled-in between the gaps between dies 4208. In one embodiment, planarization, such as mechanical mechanism polishing, is utilized to finish reconstituted wafer 4213.

A further discussion regarding FIGS. 41, 42A-42N, 43 and 44A-44F is provided below.

The following starting point is assumed: one or more types of dies 4208 that are present on one or more source substrates 105, which could be a tape film or a glass carrier wafer to which die 4208 are attached using either adhesive or direct bond (e.g., fusion bond, hybrid bond, covalent bond, etc.) or some other manner of die carrying mechanism, such as gel-pack, waffle-pack, etc. In one embodiment, die 4208 are arranged at SiP pitch (where SiP pitch is the pitch along one or more of the x and y axes or a combination thereof, of the System-in-Packages or SiPs on a product substrate (e.g., product substrate 1604), prior to dicing of the product substrate into individual SiPs) on source substrate 105. If said die 4208 are arranged at a pitch that is different from the SiP pitch along either x or y axes (SPPx, SPPy), a pick-and-place tool could be used to pick dies 4208 from source substrate 105 and populate an intermediate source substate with die 4208 at SiP pitch. In one embodiment, the pick-and-place tool is a high-throughput system (over-1000 chips-per-hour or cph, over-2000 cph, over-5000 cph, over-10000 cph, over-20000 cph, over-50000 cph or over 100000 cph). In one embodiment, the pick-and-place tool is a low precision system (e.g., over-100 nm, over-250 nm, over-500 nm, over-1 μm, over-3 μm mean+3sigma overlay/alignment precision). In one embodiment, the source substrate (e.g., source substrate 105) and the intermediate source substrate are a silicon wafer, a glass wafer, a Silicon on Insulator (SOI) wafer, a sapphire wafer, a Silicon on Sapphire (SOS) wafer, a glass on silicon wafer, a substrate with a buried sacrificial layer, a polymer film, a polymer plate, a glass plate, tape, tape with frame, tape film, backgrinding tape, backgrinding film, a transfer wafer, a carrier wafer, a product wafer, a 50 mm, 100 mm, 150 mm, 200 mm, 300 mm or 450 mm diameter circular substrate, a square substrate, a rectangular substrate, etc. Die 4208 on the source substrate (e.g., source substrate 105) could be oriented circuit side facing away from the source substrate or circuit side facing towards the source substrate (with the die backside facing away from the source substrate). The die transfer from the source substrate (e.g. source substrate 105) to the intermediate source substrate could be implemented without flipping the die orientation. In another embodiment, the die orientation is flipped prior to placing the die on the intermediate source substrate by the pick-and-place tool.

The following description is based on FIGS. 41 and 42A-42N. In one embodiment, dies 4208 are picked-and-placed onto wafer 4203 (e.g., transfer/carrier substrate). Dies 4208 may be placed in a die-by-die manner using a pick-and-place tool, or alternatively, in a multi-die manner, or alternatively, as part of an entire un-diced source substrate (for instance, using a wafer to wafer bonder). In one embodiment, dies 4208 are placed either with the circuit side facing wafer 4203 (e.g., transfer/carrier substrate) or with the circuit side facing away from wafer 4203 (e.g., transfer/carrier substrate). In one embodiment, dies 4208 are attached to wafer 4203 (e.g., transfer/carrier substrate) using fluid, liquid, adhesive, adhesive in liquid form, Light Switchable Adhesive (LSA), high-temperature LSA (for instance, with melting point above 150° C., 200° C., 300° C. or 400° C., with potentially inorganic components to achieve said high melting point), photoresist, nanoimprint resist, UV-curable adhesive, adhesive in gel form, adhesive in solid form, spin-coated liquid, inkjetted liquid, drop cast liquid, vapor condensed liquid, sub-10 μm-thick liquid, sub-5 μm-thick liquid, sub-2 μm-thick liquid, sub-1 μm-thick liquid, sub-500 nm-thick liquid, sub-200 nm-thick liquid, sub-100 nm-thick liquid, sub-50 nm-thick liquid, sub-20 nm-thick liquid, sub-10 nm-thick liquid, direct bonding, fusion bonding, hybrid bonding, mass reflow, eutectic bonding, anodic bonding, covalent bonding, thermocompression bonding, etc. In one embodiment, water is dispensed on wafer 4203 (e.g., transfer/carrier substrate) prior to the die attachment using spin coating, inkjetting, drop casting, vapor condensation, etc. In one embodiment, wafer 4203 (e.g., transfer/carrier substrate) is comprised of one or more of the following: a silicon wafer, a glass wafer, a Silicon on Insulator (SOI) wafer, a sapphire wafer, a Silicon on Sapphire (SOS) wafer, glass on silicon wafer, a substrate with a buried sacrificial layer, polymer film, a polymer plate, a glass plate, tape, tape frame, tape film, backgrinding tape, backgrinding film, a transfer wafer, a carrier wafer, a product wafer, a 50 mm, 100 mm, 150 mm, 200 mm, 300 mm or 450 mm diameter circular substrate, a square substrate and a rectangular substrate. In one embodiment, wafer 4203 (e.g., transfer/carrier substrate) comprises nanostructures. In one embodiment, once attached onto wafer 4203 (e.g., transfer/carrier substrate), any un-diced known bad die (e.g., die 4205) could be diced using a dicing method, such as plasma dicing, chemical dicing and MACE-based dicing, where laser ablation, photolithography, mechanical dicing, nanoimprint lithography, DUV lithography, 193 nm immersion lithography, EUV lithography and/or 365 nm lithography are used for patterning of the resist layer for the plasma/chemical/MACE-based dicing methods. The known bad dice (e.g., die 4205) could subsequently be removed using a pick-and-place tool, and replaced with known good dice (e.g., die 4210) from buffer wafer 4201. The pick and place could be implemented in die-by-die or multiple-die-by-die manner. In one embodiment, the bad die removal is enabled by liquification of a light switchable adhesive 4211 (for instance, using UV light incident from the underside of a transparent transfer/carrier substrate using an optionally addressable light source, such as a LED array, fiber optic source, scannable source, etc.), or alternatively, if the bad die are fusion bonded to wafer 4203 (e.g., transfer/carrier substrate) by applying a pickup force that is greater than the adhesion force of the fusion bond (where, in one embodiment, no annealing is performed after said fusion bonding of the die to wafer 4203 (e.g., transfer/carrier substrate), or in another embodiment, an annealing step is performed up to a suitable low temperature, such as sub-100° C., sub-200° C. or sub-300° C.). In one embodiment, the good die (e.g., die 4210) from buffer wafer 4201 replacing the bad die (e.g., die 4205) has been precision thinned on buffer wafer 4201 itself so as to match the thickness of the adjacent die, or alternatively, is first picked and placed onto wafer 4203 (e.g., transfer/carrier substrate) and then thinned to a matching thickness. In one embodiment, the thickness matching is performed in one or more of the following ways: the average thickness of the replaced die is matched with the average thickness of the neighboring dice, the average thickness of the replaced die is matched with the average of the thickness at the shared edges with the neighboring dice, the thickness at the shared edges is matched so that the step change in thickness when traversing from a neighboring die to the replaced good die is less than one of 1 μm, 500 nm, 200 nm, 100 nm, 50 nm, 20 nm or 10 nm. In one embodiment, the good die (e.g., die 4210) that replaced the bad die (e.g., die 4205) could subsequently be aligned with respect to one or more of the neighboring die or to wafer 4203 (e.g., the transfer/carrier substrate). In one embodiment, the dies above (known good/bad) contain alignment marks on their front-side or back-side created, for instance, using sub-micrometer plasma dicing, or sub-micrometer MACE, or etched marks on the die back-side registered to the front-side. In one embodiment, the marks are moiré type, box-in-box type, etc. In one embodiment, wafer 4203 (e.g., transfer/carrier substrate) is transparent. In one embodiment, wafer 4203 contains a set of alignment marks that are complementary to the die alignment marks. Subsequently, gap-fill, planarization and bonding (for instance, onto a product substrate 1604 in a wafer-to-wafer manner from the transfer/carrier substrate) steps are performed. In one embodiment, the bonding is one or more of the following types: eutectic bonding, thermocompression bonding, direct bonding, hybrid bonding, anodic bonding, fusion bonding, covalent bonding, bonding using a thin layer of dispensed adhesive, etc.

In one embodiment, one or more of the source substrates 105, intermediate substrates, transfer substrates 104, carrier substrates 202, product substrates 1604, dies and fields are comprised of nanostructures. In one embodiment, the nanostructures are one or more of the following: nanowires, nanopillars, microwires and micropillars. In one embodiment, the nanostructures are absent wherever an island is to be found, where an island is defined to comprise one or more of Through Silicon Vias (TSVs), metal pads and oxide spacers (that have been created around metal pads). In one embodiment, the nanostructures comprise islands (for instance, an exemplar nanostructure includes oxide spacers around metal pads created by an oxide etch step, where optionally said oxide etch step is a high-aspect ratio etch). In one embodiment, the nanostructures are fabricated in one or more of the following materials: silicon, polysilicon, amorphous silicon, silicon oxide, silicon nitride, SiCN, carbon, polymers, ceramics, aluminum oxide, metals, etc. In one embodiment, a particle lands at a bonding interface resulting in an exclusion zone that is at least two times smaller than a bonding process with bonding surfaces with no nanostructures. The presence of the nanostructures on one or more of the two surfaces being bonded could be used to reduce the exclusion zone created by an interfacial particle compared to the default case in which no nanostructures are present or more generally to enhance the yield during a bonding process. The exclusion zone could be reduced by 50%, 80%, 90% or 99%, and even be fully reduced. In one embodiment, the mode of the exclusion zone reduction is one or more of the following: bending of the nanostructures, buckling of the nanostructures (when the load on said nanostructures is beyond a certain threshold), collapse of the nanostructures, fracture of the nanostructures, permanent deformation of the nanostructures, etc. The presence of said nanostructures may reduce the area of contact during said bonding to less than 99%, 95%, 90%, 70%, 50%, 25%, 10%, 5%, 2% or 1% of the area of the first or second bonding surfaces. In one embodiment, the nanostructures are designed so as to keep the area of contact low enough to reduce particle events (i.e., particles landing on top of one of the nanostructures and causing it to bend/buckle/collapse/fail), while also optionally keeping the area large enough to allow/maximize axial conduction of heat through the bonding interface, and also, in some cases, to optionally allow enough lateral space to allow lateral transport of cooling fluids (such as air, water, coolants, etc.). In one embodiment, the nanostructures are created using Reactive Ion Etching (RIE), MACE, Ru MACE (with the patterning process being photolithography, Nanoimprint Lithography (NIL), etc.). In one embodiment, the nanostructures are created on the backside of the die. Alternatively, in one embodiment, the nanostructures are present on the frontside of the die (on polysilicon, for instance). Alternatively, the nanostructures are only present on a bulk substrate onto which die are attached. In one embodiment, nanostructures, such as nanowires, are non-straight (or offset, or kinked) so as to improve the bending/buckling/collapsing tendency of un-sparse nanostructures. In one embodiment, such nanostructures are fabricated using a MACE-based process.

In one embodiment, in-liquid align is performed during the bonding of two surfaces at least one of which has the above nanostructures. The liquid (e.g., water, isopropyl alcohol, other aqueous solutions, vapor condensate, etc.) is dispensed in discreate regions on one or both of the two surfaces. This could facilitate the evaporation of said liquid during/after bonding through the gaps between the discrete regions. In one embodiment, the volume, size or other dispensing parameters of the water dispensing could be so as to fill a height slightly larger than the nanostructures at the beginning of the bonding (to allow in-liquid alignment) and to be lesser than the height of the nanostructures as the bonding progresses.

In one embodiment, the above nanostructures are delaminated from the substrate they are bonded to using one or more of the following methods: etching away of the interfacial silicon oxide (using HF, vapor HF, localized vapor HF, etc.), or alternatively, simple delamination using vacuum pulling (ideally done prior to anneal or prior to high temperature anneals that use anneal temperatures that are beyond 200° C. for instance).

Consider a process that can be used to create a substrate populated with two or more known good die (a 2D layer, for instance), where the two or more dice are bonded onto the substrate using direct bonding, fusion bonding and/or hybrid bonding techniques, and where the mean thickness of the two or more dies is substantially the same (or matched in a manner described previously). A 2.5D device is defined as a device created using the above process with metallization on top of the optional 2D layer of known good die, or alternatively, an interposer bonded on top of the 2D layer of known good die. A 3D device is defined as a device created using the above process with one or more layers of transistors fabricated or integrated/bonded on top of the optional 2D layer of known good die.

Furthermore, in one embodiment, bad die with good die substitution and alignment are performed either in the same step (where the bonding heads that pick-and-place dice also align them precisely), or two sets of steps (where a first set of one-or-more bonding heads pick-and-place dice imprecisely, and a second set of one-or-more bonding heads align the dice precisely).

In one embodiment, a dicing technique, such as plasma dicing, is used that allows retention of alignment marks in the dice.

In one embodiment, alignment metrology of good dice from buffer wafer 4201 to neighboring dice on source wafer (e.g., source wafer 105) are performed using IR moiré metrology (similar to the techniques used in Nanoimprint Lithography).

In one embodiment, die actuation, with adhesive in liquid state, is performed using short-stroke stages and/or stage actuation (using closed-loop feedback from the metrology components, such as moiré microscopes).

In one embodiment, an alternative method for metrology is to pick up the entire reconstituted source wafer and take them to a separately-located metrology station. Die alignment correction, in this case, is performed in an open-loop manner.

An alternative embodiment to performing Precision Die Thinning (PDT) on buffer wafer 4201 is to pick un-thinned dice from buffer wafer 4201 and precision thin them once they have been placed on wafer 4203 (e.g., transfer/carrier wafer).

In one embodiment, reconstituted substrates for F2F W2W bonding are created by implementing a wafer-scale transfer on the face-down reconstituted wafers (created previously) to a second transfer/carrier substrate.

It is noted that adhesives (for instance, the LSA) might not remain thermo-mechanically stable at the annealing temperature for fusion/hybrid bonding. After W2W bonding of the reconstituted wafers (e.g., reconstituted wafer 4213), wafer 4203 (e.g., transfer/carrier wafer) and the adhesives are removed right away. Alternatively, the fusion/hybrid bonded wafers with adhesives present and wafer 4203 (e.g., transfer/carrier wafer) attached are partially annealed to a temperature at which the adhesives remain thermo-mechanically stable (˜100° C., for instance), and subsequently remove the LSA and wafer 4203 (e.g., transfer/carrier wafer) prior to a full anneal.

In one embodiment, one or more of the above processes are used to create one or more of the following: a semiconductor device, System-in-Packages (SiPs), a 2.5D integrated device, a 3D integrated device, High Bandwidth Memory (HBM), logic over SRAM device, SRAM over logic device, DRAM over logic device, logic over DRAM device, logic over memory device, memory over logic device, logic over imager array, imager array over logic, a face to face (F2F) integrated device (where at least one bonded layer includes a first circuit layer and a second circuit layer where the circuit side of the two layers face each other), a face to back (F2B) integrated device (where at least one bonded layer includes a first circuit layer and a second circuits layer where the circuit side of one of the two layers faces the backside or TSV side of the other of the two layers).

In one embodiment, bonding in one or more of the above processes corresponds to one or more of the following: fusion bonding (e.g., oxide-oxide), hybrid bonding (e.g., oxide-oxide, metal-metal), direct bonding, anodic bonding, covalent bonding, eutectic bonding and adhesive bonding.

As a result of the foregoing, the principles of the present invention provide a means for improving the precision in integrating separately manufactured components into a higher level assembly (System-in-Package (SiP)). That is, the principles of the present invention provide a means for improving the precision in heterogeneous integration.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for enhancing a yield of a bonding process, the method comprising:
performing an etch on one or more of a first bonding surface and a second bonding surface to create nanostructures in said one or more of said first bonding surface and said second bonding surface; and
bonding said first bonding surface with said second bonding surface, wherein a particle lands at a bonding interface resulting in an exclusion zone that is at least two times smaller than a bonding of two bonding surfaces with no nanostructures.

2. The method as recited in claim 1, wherein presence of said nanostructures reduces an area of contact during said bonding to less than one of 50%, 25%, 10%, 5%, 2% and 1% of an area of said first or second bonding surface.

3. The method as recited in claim 1, wherein said bonding comprises one of the following: fusion bonding, hybrid bonding, direct bonding, anodic bonding, covalent bonding and adhesive bonding.

4. The method as recited in claim 1, wherein said bonding is utilized for face to face bonding or face to back bonding.

5. The method as recited in claim 1, wherein said bonding is utilized for creation of one or more of the following: 2.5D devices, 3D devices, High Bandwidth Memory (HBM), logic over SRAM, SRAM over logic, DRAM over logic, logic over DRAM, logic over memory, memory over logic, logic over imager array and imager array over logic.

6. The method as recited in claim 1, wherein said nanostructures are absent wherever one or more island structures are to be found.

7. The method as recited in claim 1 further comprising:
delaminating a bond between said first bonding surface and said second bonding surface, wherein hydrofluoric acid or vapor hydrofluoric acid is used to delaminate said bond between said first bonding surface and said second bonding surface.

8. The method as recited in claim 1, wherein said first and second bonding surfaces are delaminated using a mechanical pulling approach.

9. The method as recited in claim 1 further comprising:
performing in-liquid alignment during said bonding.

10. The method as recited in claim 1, wherein said nanostructures are kinked to enhance their ability to reduce particle-induced exclusion zones at said bonding interface.

11-23. (canceled)
